(19) United States
(12) Patent Application Publication
(10) Pub. No.: US 2026/0068403 A1
(43) Pub. Date: Mar. 5, 2026

(54) Display Device

(71) Applicant: LG Display Co., Ltd., Seoul (KR)

(72) Inventors: Won Sub So, Paju-si (KR); Dong Hyun Chung, Paju-si (KR); Woo Jin Seong, Paju-si (KR); Young Hyun Son, Paju-si (KR); Seok Mun Bae, Paju-si (KR); Jong Won Lee, Paju-si (KR); Hyoung Sun Park, Paju-si (KR); Jung Im Choi, Paju-si (KR); Sung Jin An, Paju-si (KR)

(21) Appl. No.: 19/249,816

(22) Filed: Jun. 25, 2025

(30) Foreign Application Priority Data
Sep. 3, 2024 (KR) 10-2024-0118938

(51) Int. Cl. H10H 29/855; H10H 29/34; H10H 29/37; H10H 29/49; H10H 29/80; H10H 29/853

(52) U.S. Cl. CPC H10H 29/855; H10H 29/34; H10H 29/37; H10H 29/49; H10H 29/842; H10H 29/853

(57) ABSTRACT

Disclosed herein may be a display device including a display panel, the display panel including: a substrate; an insulating layer located on the substrate; a plurality of first electrodes arranged on the insulating layer; a plurality of light-emitting elements arranged on the plurality of first electrodes; a plurality of second electrodes arranged on the plurality of light-emitting elements; an optical layer enclosing the plurality of light-emitting elements; a cover layer located on the optical layer; at least one pattern located on the cover layer; a cover adhesive layer covering the at least one pattern; and a cover located on the cover adhesive layer. The cover may include a planar area, and a curved area formed around the planar area.

### CROSS-REFERENCE TO RELATED APPLICATION

This application claims priority to and the benefit of Republic of Korea Patent Application No. 10-2024-0118938, filed on Sep. 3, 2024, which is hereby incorporated by reference in its entirety.

### BACKGROUND

### Field

The present specification relates to a display panel and a display device including the display panel.

### Discussion of Related Art

Display devices are applied to various electronic devices such as a television (TV), a mobile phone, a laptop, and a tablet.

The display devices include an organic light emitting display (OLED) that is self-emissive, a liquid crystal display (LCD) that requires a separate light source, and the like.

Recently, a display device including a light-emitting element (e.g., a light-emitting diode; LED) has been attracting attention as a next-generation display device. Since the light-emitting element is formed of an inorganic material rather than an organic material, the light-emitting element has a faster lighting speed, superior luminous efficiency, and can display an image with high luminance compared to the LCD or the OLED.

A micro LED may be used as the light-emitting element, and the micro-LED may be used as a pixel of a display device. Furthermore, the micro-LED may achieve high luminance.

The display device includes a cover located on the light-emitting element, and the cover may include a curved surface located adjacent to an edge thereof.

Scattered light of the light emitted from the light-emitting element is emitted toward an edge side of the cover, and the light emitted toward the edge side may be refracted by the curved surface of the cover. Accordingly, the light emitted from the light-emitting element may be refracted by the curved surface of the cover toward a side of the display device (or display panel). Furthermore, the light refracted toward the side of the display device (or display panel) may form mura on the curved surface of the cover. For example, when viewing the display device from the side of the display device, a luminance difference may occur due to the light refracted toward the side of the display device (or display panel), and such a luminance difference may form mura on the curved surface of the cover. The mura may appear more pronounced at oblique viewing angles. Here, a location from which a user views the display device from the side of the display device may be referred to as an oblique viewing angle.

Accordingly, mura visible at oblique viewing angles may degrade the display quality of the display device, and the degradation of the display quality may reduce the reliability of the display device.

### SUMMARY

Embodiments of the present specification are directed to a display panel and a display device including the display panel, which prevent, reduce, or minimize occurrence of mura at oblique viewing angles using patterns.

Embodiments of the present specification are directed to a display panel and a display device including the display panel, which can provide various embodiments for the size, arrangement positions, and the like of patterns disposed in the display panel to enhance design flexibility.

The objectives to be solved by the embodiments of the present disclosure are not limited to the objectives mentioned above, and other objectives not mentioned will be clearly understood by those skilled in the art from the following descriptions.

A display device according to an embodiment of the present specification may include a display panel, the display panel comprising: a substrate; an insulating layer located on the substrate; a plurality of first electrodes arranged on the insulating layer; a plurality of light-emitting elements arranged on the plurality of first electrodes; a plurality of second electrodes arranged on the plurality of light-emitting elements; an optical layer enclosing the plurality of light-emitting elements; a cover layer located on the optical layer; at least one pattern located on the cover layer; a cover adhesive layer covering the at least one pattern; and a cover located on the cover adhesive layer. The cover may include a planar area, and a curved area formed around the planar area.

According to the present specification, occurrence of mura at oblique viewing angles can be prevented, reduced, or minimized by using patterns arranged along light emission paths of light-emitting elements. Accordingly, the reliability of the display device can be improved.

According to the present specification, the display quality at oblique viewing angles can be improved by using the patterns without requiring additional compensation for luminance differences, thereby enabling low-power operation of the display device.

According to the present specification, the design flexibility of the display device can be improved by adjusting the size, shape, arrangement positions, and the like of the patterns.

The effects of the present disclosure are not limited to the effects mentioned above, and other effects not mentioned will be clearly understood by those skilled in the art to which the technical idea of the present disclosure pertains from the following description.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is an exploded perspective view illustrating a display device according to an embodiment of the present specification;

FIG. 2 is a plan view illustrating the display device according to an embodiment of the present specification;

FIG. 3 is an enlarged partial view illustrating the display device according to an embodiment of the present specification;

FIG. 4 is a diagram illustrating a circuit structure in the display device according to an embodiment of the present specification;

FIG. 5 is a partial plan view illustrating the display device according to an embodiment of the present specification;

FIG. 6 is a partial plan view illustrating the display device according to an embodiment of the present specification;

FIG. 7 is a partial plan view illustrating the display device according to an embodiment of the present specification;

FIG. 8 is a sectional view illustrating a display panel of the display device taken along line I-I′ of FIG. 3 according to an embodiment of the present specification;

FIG. 9 is a partial sectional view illustrating a subpixel of the display device according to an embodiment of the present specification;

FIG. 10 is a diagram illustrating a first electrode of the display device according to an embodiment of the present specification;

FIG. 11 is a diagram illustrating an arrangement relationship between the first electrode and a passivation layer of the display device according to an embodiment of the present specification;

FIG. 12 is a sectional view illustrating a display panel of a display device corresponding to a sectional view taken along line II-II′ of FIG. 2 according to a comparative example;

FIG. 13 is a sectional view illustrating a display panel of a display device taken along line II-II′ of FIG. 2 according to another embodiment of the present specification;

FIG. 14 is a plan view illustrating patterns arranged in the display panel according to another embodiment of the present specification;

FIG. 15 is a diagram illustrating the scattered light efficiency of the display panel according to the comparative example, the scattered light efficiency of the display panel according to another embodiment, and the height of the pattern, based on a planar area and a curved area of a cover arranged in the display panel;

FIG. 16 is a sectional view illustrating a display panel of a display device taken along line II-II′ of FIG. 2 according to another embodiment of the present specification;

FIG. 17 is a plan view illustrating patterns arranged in the display panel according to another embodiment of the present specification;

FIG. 18 is a diagram illustrating the scattered light efficiency of the display panel according to the comparative example, the scattered light efficiency of the display panel according to another embodiment, and the height of the pattern, based on a planar area and a curved area of a cover arranged in the display panel;

FIG. 19 is a sectional view illustrating a display panel of a display device taken along line II-II′ of FIG. 2 according to another embodiment of the present specification;

FIG. 20 is a plan view illustrating patterns arranged in the display panel according to another embodiment of the present specification;

FIG. 21 is a diagram illustrating the scattered light efficiency of the display panel according to the comparative example, the scattered light efficiency of the display panel according to another embodiment, and the height of the pattern, based on a planar area and a curved area of a cover arranged in the display panel;

FIG. 22 is a sectional view illustrating a display panel of a display device taken along line II-II′ of FIG. 2 according to another embodiment of the present specification;

FIG. 23 is a sectional view illustrating a display panel of a display device a taken along line II-II′ of FIG. 2 according to another embodiment of the present specification; and

FIGS. 24 to 27 are diagrams illustrating devices to which the display device according to embodiments of the present specification is applied.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, and “having” used herein are generally intended to allow other components to be added unless the terms are used with the term “only”. References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

When describing a temporal contextual relationship is described, such as “after,” “following,” “next to,” or “before,” it may also include non-contiguous cases unless “immediately” or “directly” is used.

In the description for the embodiments, the first, second, etc. are used to describe various components, but these components are not limited by these terms. These terms are only used to distinguish one component from another. Therefore, the first component mentioned below may be a second component within the technical spirit of the present disclosure.

Terms such as first, second, A, B, (a), (b), and the like may be used to describe elements of the embodiments of the present specification. Such terms are intended only to distinguish one component from another and are not intended to define the nature, sequence, order, or number of such components.

When a component is described as “connected,” “coupled,” or “attached” to another component, it is to be understood that the component may be directly connected or attached to the other component, but that there may also be other components “interposed” between the respective components which may be indirectly connected or attached where not specifically stated.

When a component or layer is described as “contacting” or “overlapping” another component or layer, the component or layer may directly contact or overlap the other component or layer, but unless there is a specific statement, it should be understood that other components may be interposed between the components that are indirectly contacting or overlapping.

It should be understood that the term “at least one” includes all possible combinations of one or more related components. For example, the meaning of “at least one of the first, second, and third components” includes not only the first, second, or third component, but also any combination of two or more of the first, second, and third components.

“First direction,” “second direction,” “third direction,” “X-axis direction,” “Y-axis direction,” and “Z-axis direction” should not be interpreted only as geometric relationships that are perpendicular to each other, but may mean a broader directionality within the range that the configuration of the present specification may function.

The following embodiments may be combined or associated with each other in whole or in part, and various types of interlocking and driving are technically possible. The embodiments may be implemented independently of each other or together in an interrelated relationship.

Hereinafter, preferred embodiments of the present disclosure will be described in detail with reference to the accompanying drawings.

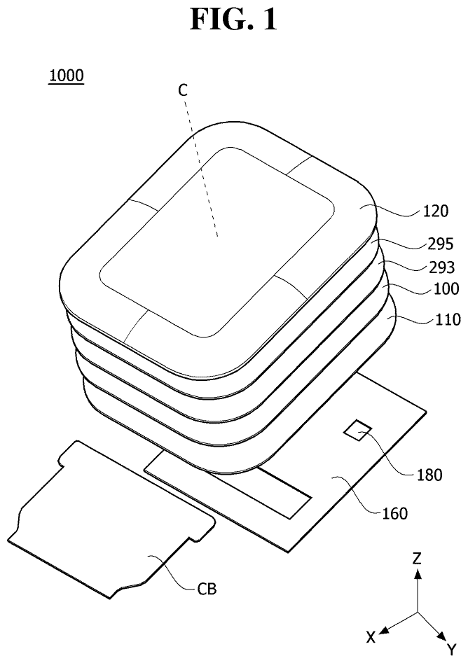

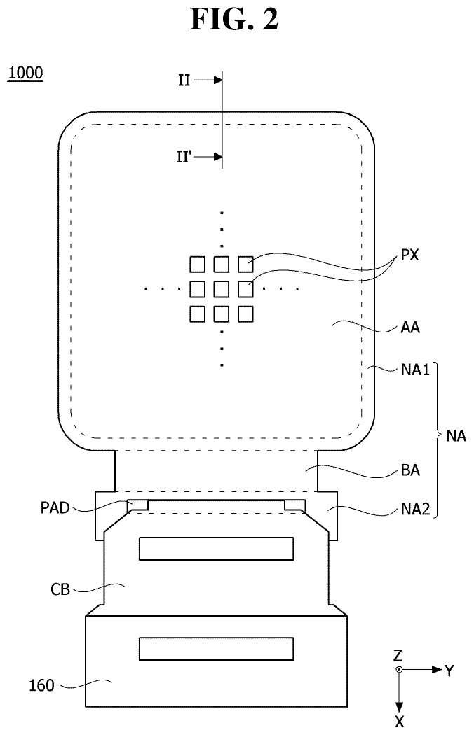

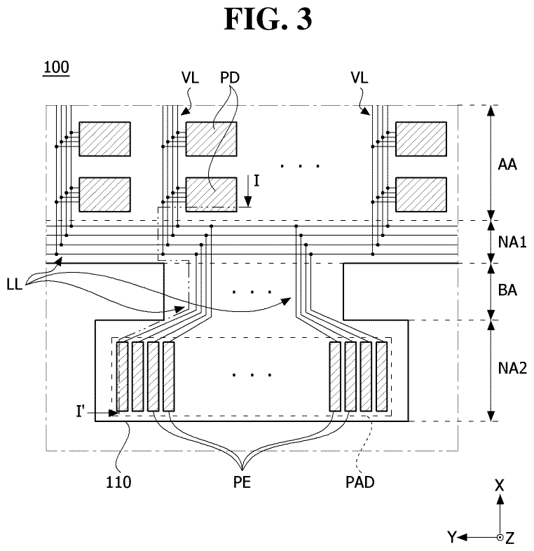

FIG. 1 is an exploded perspective view illustrating a display device according to an embodiment of the present specification. FIG. 2 is a plan view illustrating the display device according to an embodiment of the present specification. FIG. 3 is a partial enlarged view illustrating the display device according to an embodiment of the present specification. The reference symbol C shown in FIG. 1 may indicate a center of a display device 1000 and/or a display panel 100 on a horizontal plane.

Referring to FIGS. 1 to 3, the display device 1000 according to an embodiment of the present specification may include the display panel 100, which may include a polarizing layer 293, a cover adhesive layer 295, a cover 120, and a substrate 110. The display device 1000 may also include a flexible circuit board CB and a printed circuit board 160.

The substrate 110 may be a component that supports other components of the display device 1000. The substrate 110 may be formed of an insulating material. The substrate 110 may be formed of glass, resin, or the like. Furthermore, the substrate 110 may be formed of a material having flexibility. For example, the substrate 110 may be formed of a plastic material having flexibility, such as polyimide (PI). However, embodiments of the present specification are not limited thereto.

The display panel 100 may implement the display of information, video, and/or images provided to a user. For example, the display panel 100 may include a display area AA and a non-display area NA. For example, the substrate 110 may include the display area AA and the non-display area NA. The display area AA and the non-display area NA are not limited to being described only with respect to the substrate 110 but may be described across the entire display device 1000.

The display area AA may be an area where an image is displayed. The display area AA may include a plurality of pixels PX. Each of the plurality of pixels PX may include a plurality of sub-pixels. A plurality of light emitting elements may be arranged in each of the plurality of sub-pixels. The configuration of the plurality of light emitting elements may vary depending on the type of the display device 1000. For example, in the case where the display device 1000 is an inorganic light emitting display, each of the light emitting elements may be a light-emitting diode (LED), a micro light-emitting diode (micro LED), or a mini light-emitting diode (mini LED); however, embodiments of the present specification are not limited thereto.

The non-display area NA may be an area where no image is displayed. Various wires, circuits, and the like for driving the plurality of pixels PX in the display area AA may be arranged in the non-display area NA. For example, various wires and a driving circuit may be formed in the non-display area NA, and a pad portion PAD, to which an integrated circuit, a printed circuit, and the like are connected, may be located in the non-display area NA; however, embodiments of the present specification are not limited thereto.

For example, the driving circuit may be a data driving circuit and/or a gate driving circuit; however, embodiments of the present specification are not limited thereto. Wires for supply of control signals provided to control the driving circuits may be arranged on the display panel 100. For instance, the control signals may include various timing signals, including a clock signal, an input data enable signal, and synchronization signals; however, embodiments of the present specification are not limited thereto. The control signals may be received through the pad portion PAD. For example, link wires LL for transmitting signals may be arranged in the non-display area NA. For instance, driving components such as the flexible circuit board CB and the printed circuit board 160 may be connected to the pad portion PAD.

According to the present specification, the non-display area NA may include a first non-display area NA1, a bending area BA, and a second non-display area NA2. For example, the first non-display area NA1 may be an area that encloses at least a portion of the display area AA. The bending area BA may be an area extending from at least one of a plurality of sides of the first non-display area NA1 and may be a bendable area. The second non-display area NA2 may be an area extending from the bending area BA. The pad portion PAD may be located in the second non-display area NA2. For example, the bending area BA may be in a bent state, and a remaining area of the substrate 110, other than the bending area BA, may be in a flat state. In this case, as the bending area BA bends, the second non-display area NA2 may be positioned over a rear surface of the display area AA. However, embodiments of the present specification are not limited thereto.

The display area AA of the substrate 110 or the display device 1000 may be formed in various shapes depending on the design of the display device 1000. For example, the display area AA may be formed in a rectangular shape with four rounded corners. However, embodiments of the present specification are not limited thereto. In another example, the display area AA may be formed in a rectangular shape with four right-angled corners or in a circular shape. However, embodiments of the present specification are not limited thereto.

According to the present specification, the width of the second non-display area NA2, in which a plurality of pad electrodes PE are arranged, may be greater than the width of the bending area BA, in which only a plurality of link wires LL are arranged. Furthermore, the width of the display area AA, in which a plurality of sub-pixels are arranged, may be greater than the width of the bending area BA, in which only the plurality of link wires LL are arranged. Although in the drawings the width of the bending area BA is illustrated as being smaller than that of other areas of the substrate 110, the shape of the substrate 110, including the bending area BA, is merely illustrative, and embodiments of the present specification are not limited thereto.

Referring to FIG. 3, a plurality of pixel driving circuits PD may be arranged in the display area AA. The plurality of pixel driving circuits PD may be circuits configured to drive the light-emitting elements of the plurality of sub-pixels. Each of the plurality of pixel driving circuits PD may include a plurality of transistors including a driving transistor, a storage capacitor, and the like, and may supply control signals, power, and drive current to the light-emitting elements of a plurality of corresponding sub-pixels to control emission operations of the light-emitting elements. For example, each pixel driving circuit PD may include a power wire, and a signal wire provided to control the on/off state of emission and/or the emission time of the light-emitting elements. For instance, the plurality of pixel driving circuits PD may each be a driver fabricated on a semiconductor substrate through a metal-oxide-silicon field effect transistor (MOSFET) fabrication process, but embodiments of the present specification are not limited thereto. The driver may include a plurality of pixel driving circuits PD and may drive a plurality of sub-pixels.

Referring also to FIG. 1, the flexible circuit board CB and the printed circuit board 160 may be located below the display panel 100. The flexible circuit board CB and the printed circuit board 160 may be located on at least one side edge of the display panel 100, but embodiments of the present specification are not limited thereto. One side of the flexible circuit board CB may be attached to the display panel 100, and another side thereof may be attached to the printed circuit board 160; however, embodiments of the present specification are not limited thereto. The flexible circuit board CB may be a flexible film, but embodiments of the present specification are not limited thereto.

The pad portion PAD including the plurality of pad electrodes PE is located in the second non-display area NA2. A driving component including at least one flexible circuit board (or flexible film) CB and the printed circuit board 160 may be attached or bonded to the pad portion PAD. The plurality of pad electrodes PE of the pad portion PAD may be electrically connected to the at least one flexible circuit board (or flexible film) CB and may transmit various signals (or power) from the printed circuit board 160 and the flexible circuit board (or flexible film) CB to the plurality of pixel driving circuits PD in the display area AA.

The flexible circuit board (or flexible film) CB may be a film in which various components are arranged on a base film having flexibility. For example, a driving integrated circuit (IC), such as a gate driver IC or a data driver IC, may be arranged on the flexible circuit board (or flexible film) CB, but embodiments of the present specification are not limited thereto. The driving IC may be a component that processes data and driving signals for displaying an image. The driving IC may be arranged by a method, such as chip on glass (COG), chip on film (COF), or tape carrier package (TCP), depending on the mounting method; however, embodiments of the present specification are not limited thereto. The flexible circuit board (or flexible film) CB may be attached or bonded onto the plurality of pad electrodes PE through a conductive adhesive layer, but embodiments of the present specification are not limited thereto.

The printed circuit board 160 may be a component that is electrically connected to the at least one flexible circuit board (or flexible film) CB and configured to supply signals to the driving IC. The printed circuit board 160 may be located on one side of the flexible circuit board (or flexible film) CB and may be electrically connected to the flexible circuit board (or flexible film) CB. Various types of components configured to supply different signals to the driving IC may be arranged on the printed circuit board 160. For example, various components, such as a timing controller, a power supply unit, a memory, a processor, or the like may be arranged on the printed circuit board 160. For instance, the printed circuit board 160 may include a power management integrated circuit (PMIC); however, embodiments of the present specification are not limited thereto.

The printed circuit board 160 may include at least one hole 180, but embodiments of the present specification are not limited thereto. An internal component configured to detect ambient light, temperature or the like, which can be provided to a plurality of sensors, may be located in an area corresponding to the at least one hole 180. For example, the internal component may include an ambient light sensor (ALS), a temperature sensor, or the like, but embodiments of the present specification are not limited thereto. For instance, the hole 180 may be a through-hole or the like; however, embodiments of the present specification are not limited thereto.

Referring to FIG. 1, the polarizing layer 293 may be located on the display panel 100. The polarizing layer 293 may prevent or reduce light generated from an external light source from entering the display panel 100 and affecting the light-emitting elements or the like.

The cover 120 may be located on the polarizing layer 293. The cover 120 may be a component provided to protect the display panel 100. A cover adhesive layer 295 may be located between the polarizing layer 293 and the cover 120. The cover 120 may be attached to the display panel 100 by the cover adhesive layer 295. The cover adhesive layer 295 may include an optically clear adhesive (OCA), an optically clear resin (OCR), a pressure sensitive adhesive (PSA), or the like, but embodiments of the present specification are not limited thereto.

The substrate 110 may be located between the display panel 100 and the printed circuit board 160. The substrate 110 may reinforce the rigidity of the display panel 100. The substrate 110 may be a backplate, however, embodiments of the present specification are not limited thereto.

Referring to FIGS. 1 to 3, a plurality of link wires LL may be arranged in the non-display area NA. The plurality of link wires LL may be wires that transmit various signals from the at least one flexible circuit board (or a flexible film) CB and the printed circuit board 160 to the display area AA. The plurality of link wires LL may extend from a plurality of pad electrodes PE in the second non-display area NA2 toward the bending area BA and the first non-display area NA1 and may be electrically connected to a plurality of driving wires VL in the display area AA. The plurality of pixel driving circuits PD may be driven in response to signals received from the at least one flexible circuit board (or flexible film) CB and the printed circuit board 160 through the driving wires VL in the display area AA and the link wires LL in the non-display area NA.

For example, the plurality of driving wires VL, along with a plurality of link wires LL, may be wires provided to transmit signals output from the at least one flexible circuit board (or flexible film) CB and the printed circuit board 160 to the plurality of pixel driving circuits PD. The plurality of driving wires VL may be arranged in the display area AA and may be electrically connected to each of the plurality of pixel driving circuits PD. The plurality of driving wires VL may extend from the display area AA toward the non-display area NA, and may be electrically connected to the plurality of link wires LL. Accordingly, signals output from the at least one flexible circuit board (or flexible film) CB and the printed circuit board 160 may be transmitted to each of the plurality of pixel driving circuits PD through the plurality of link wires LL and the plurality of driving wires VL.

As the bending area BA is bent, portions of the plurality of link wires LL may also be bent. Stress may be concentrated on the bent portions of the link wires LL, which may cause cracks in the link wires LL. Therefore, the plurality of link wires LL may be formed of a conductive material with excellent flexibility to reduce cracks during the bending of the bending area BA. For example, the plurality of link wires LL may be formed of a highly flexible conductive material such as gold (Au), silver (Ag), or aluminum (Al), but embodiments of the present specification are not limited thereto. Furthermore, the plurality of link wires LL may be formed of one of various conductive materials used in the display area AA. For example, the plurality of link wires LL may be formed of molybdenum (Mo), chromium (Cr), titanium (Ti), nickel (Ni), neodymium (Nd), copper (Cu), an alloy of silver (Ag) and magnesium (Mg), or other alloys thereof, but embodiments of the present specification are not limited thereto. The plurality of link wires LL may also be formed in a multilayer structure that includes various conductive materials. For example, the plurality of link wires LL may be formed in a triple-layer structure including titanium (Ti)/aluminum (Al)/titanium (Ti), but embodiments of the present specification are not limited thereto.

The plurality of link wires LL may be configured in various shapes to reduce stress. At least a portion of the plurality of link wires LL that is located in the bending area BA may extend in the same direction as the extension direction of the bending area BA or may extend in a direction different from the extension direction of the bending area BA to reduce stress. For example, in the case where the bending area BA extends in one direction from the first non-display area NA1 toward the second non-display area NA2, at least a portion of the link wires LL that is located in the bending area BA may extend in a direction inclined relative to the one direction. In another example, at least a portion of the plurality of link wires LL may be configured in patterns of various shapes. For instance, at least a portion of the plurality of link wires LL that is located in the bending area BA may have a shape in which a conductive pattern, having at least one of a diamond shape, a rhombus shape, a trapezoidal wave shape, a triangular wave shape, a sawtooth wave shape, a sine wave shape, a circular shape, or an omega (Ω) shape, is repeatedly arranged; however, embodiments of the present specification are not limited thereto. Therefore, to minimize stress concentrated on the plurality of link wires LL and the resulting cracks, the plurality of link wires LL may have various shapes, including the aforementioned shapes; however, embodiments of the present specification are not limited thereto.

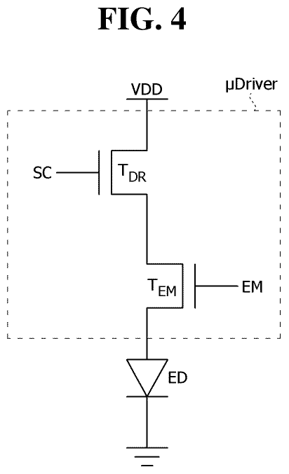

FIG. 4 is a diagram illustrating a circuit structure in the display device according to an embodiment of the present specification.

In FIG. 4, an example is illustrated in which a single light-emitting element ED is connected to a micro driver μDriver, but embodiments of the present specification are not limited thereto. For example, eight light-emitting elements ED may be connected to the single micro driver μDriver. In another example, sixteen light-emitting elements ED may be connected to the single micro driver μDriver, or thirty-two or sixty-four light-emitting elements ED may be simultaneously connected to the single micro driver μDriver. The light-emitting element ED may be a micro light-emitting element (μLED).

The single micro driver (μDriver) may include a driving transistor T_{DR} and a light-emitting transistor T_{EM}, but embodiments of the present specification are not limited thereto.

For example, the driving transistor T_{DR} may include a first electrode configured to receive a high-potential power supply voltage VDD, a second electrode connected to a first electrode of the light-emitting transistor T_{EM}, and a gate electrode configured to receive a scan signal SC. The scan signal SC that is applied to the gate electrode of the driving transistor T_{DR} may be a direct current (DC) voltage, and a fixed reference voltage (Vref) may be applied in each frame; however, embodiments of the present specification are not limited thereto.

The light-emitting transistor T_{EM} may include the first electrode connected to the second electrode of the driving transistor T_{DR}, a second electrode connected to the light-emitting element ED, and a gate electrode configured to receive an emission signal EM. The emission signal EM that is applied to the gate electrode of the light-emitting transistor T_{EM} may be a pulse width modulation (PWM) signal that varies in each frame; however, embodiments of the present specification are not limited thereto.

A first electrode of the light-emitting element ED may be connected to the second electrode of the light-emitting transistor T_{EM}, and a second electrode of the light-emitting element ED may be connected to ground. For example, the first electrode of the light-emitting element ED may be an anode electrode, and the second electrode of the light-emitting element ED may be a cathode electrode; however, embodiments of the present specification are not limited thereto.

The driving transistor T_{DR} and the light-emitting transistor T_{EM} may each be an n-type transistor or a p-type transistor.

In the micro driver μDriver, the driving transistor T_{DR} may be turned on in response to the scan signal SC applied from a timing controller (T-CON), and the light-emitting transistor T_{EM} may be turned on in response to the emission signal EM. Accordingly, a drive current may be applied to the light-emitting element ED via the driving transistor T_{DR} and the light-emitting transistor T_{EM} due to the high-potential power supply voltage VDD applied to the first electrode of the driving transistor T_{DR}, thereby allowing the light-emitting element ED to emit light.

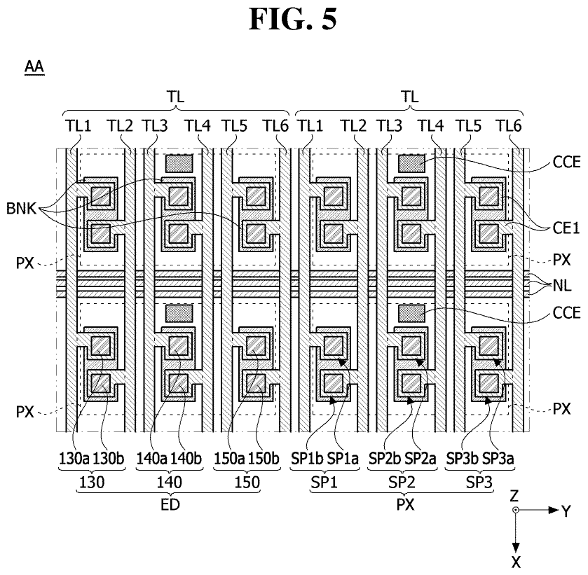

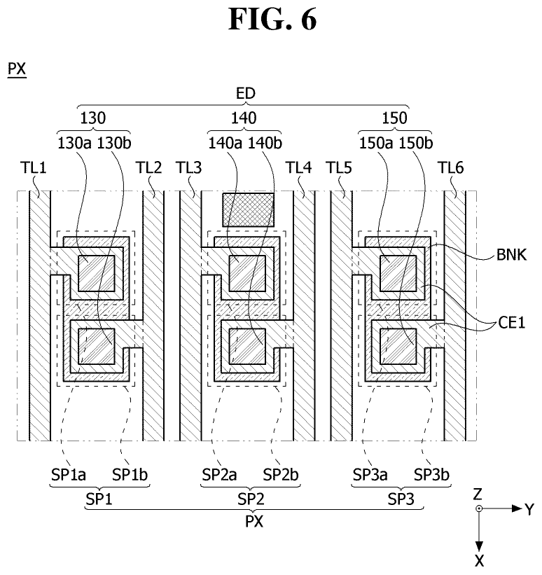

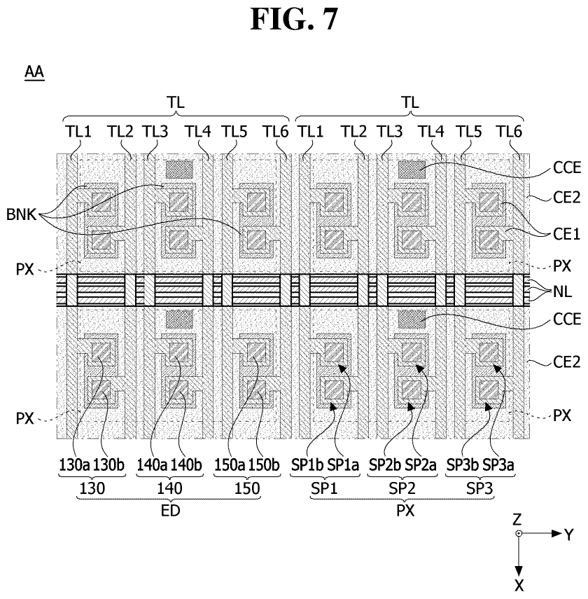

FIGS. 5 to 7 are partial plan views of the display device according to an embodiment of the present specification. For example, FIG. 5 is an enlarged partial plan view of a display area in which a plurality of pixels are included. For example, FIG. 6 is an enlarged partial plan view of a display area in which a single pixel is included. For instance, FIG. 7 is an enlarged partial plan view of a display area in which a plurality of pixels are included. In FIGS. 5 and 6, only a plurality of signal wires TL, a plurality of communication wires NL, a plurality of first electrodes CE1, a plurality of banks BNK, and a plurality of light-emitting elements ED are illustrated; however, embodiments of the present specification are not limited thereto. FIG. 7 is an enlarged partial plan view illustrating a plurality of second electrodes CE2 additionally arranged compared with FIG. 5.

Referring to FIGS. 5 and 6, a plurality of pixels PX, each formed of a plurality of sub-pixels, may be arranged in the display area AA. Each of the plurality of sub-pixels may include a light-emitting element ED and may independently emit light. The plurality of sub-pixels may be arranged in a matrix form including a plurality of rows and a plurality of columns; however, embodiments of the present specification are not limited thereto.

The plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, another may be a green sub-pixel, and a remaining one may be a blue sub-pixel. The types of the plurality of sub-pixels are illustrative, and embodiments of the present specification are not limited thereto.

Each of the plurality of pixels PX may include at least one first sub-pixel SP1, at least one second sub-pixel SP2, and at least one third sub-pixel SP3. For example, each pixel PX may include a pair of first sub-pixels SP1, a pair of second sub-pixels SP2, and a pair of third sub-pixels SP3. The pair of first sub-pixels SP1 may include a first-first sub-pixel SP1a and a first-second sub-pixel SP1b. The pair of second sub-pixels SP2 may include a second-first sub-pixel SP2a and a second-second sub-pixel SP2b. The pair of third sub-pixels SP3 may include a third-first sub-pixel SP3a and a third-second sub-pixel SP3b. For example, each pixel PX may include the first-first sub-pixel SP1a and the first-second sub-pixel SP1b, the second-first sub-pixel SP2a and the second-second sub-pixel SP2b, and the third-first sub-pixel SP3a and the third-second sub-pixel SP3b. However, embodiments of the present specification are not limited thereto.

The plurality of sub-pixels that form each pixel PX may be arranged in various ways. For example, in each pixel PX, a pair of first sub-pixels SP1 may be arranged in the same column, a pair of second sub-pixels SP2 may be arranged in the same column, and a pair of third sub-pixels SP3 may be arranged in the same column. The first sub-pixels SP1, the second sub-pixels SP2, and the third sub-pixels SP3 may be arranged in the same row. The number and arrangement of the plurality of sub-pixels that form each pixel PX are illustrative, and embodiments of the present specification are not limited thereto.

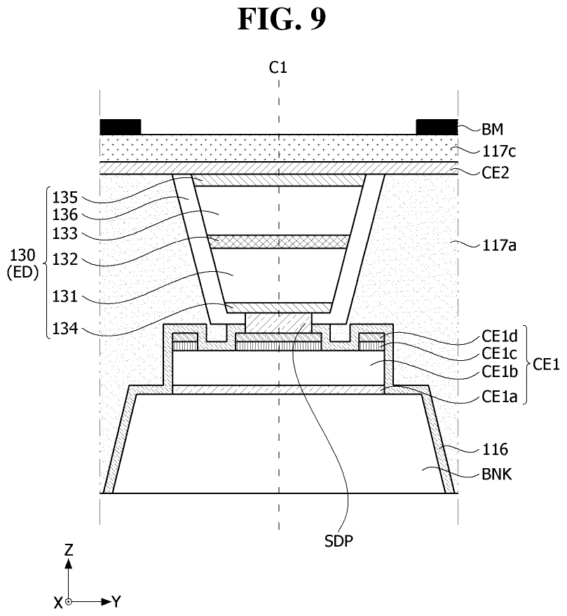

A plurality of signal wires TL may be arranged in an area between the plurality of sub-pixels. The plurality of signal wires TL may extend in a column direction between the plurality of sub-pixels. The plurality of signal wires TL may be wires that transmit an anode voltage from the pixel driving circuit PD to the plurality of sub-pixels. For example, the plurality of signal wires TL may be electrically connected to a plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal wires TL. For example, the first electrodes CE1 may be electrodes electrically connected to anode electrodes 134 (shown in FIG. 9) of the light-emitting elements ED. Accordingly, the anode voltage from the signal wires TL may be transmitted to the anode electrodes 134 of the light-emitting elements ED through the first electrodes CE1.

Accordingly, the structure of the display device 1000 may be simplified by using the pixel driving circuit PD in which a plurality of pixel circuits are integrated, instead of forming a plurality of transistors and storage capacitors in each of the plurality of sub-pixels. Furthermore, as the circuits respectively arranged in the plurality of sub-pixels in conventional display devices are integrated into a single pixel driving circuit PD, high-efficiency and low-power operation may be achieved.

The plurality of signal wires TL may include a first signal wire TL1, a second signal wire TL2, a third signal wire TL3, a fourth signal wire TL4, a fifth signal wire TL5, and a sixth signal wire TL6. The first signal wire TL1 and the second signal wire TL2 may be respectively and electrically connected to the pair of first sub-pixels SP1. The third signal wire TL3 and the fourth signal wire TL4 may be respectively and electrically connected to the pair of second sub-pixels SP2. The fifth signal wire TL5 and the sixth signal wire TL6 may be respectively and electrically connected to the pair of third sub-pixels SP3.

The first signal wire TL1 may be located on one side of the pair of first sub-pixels SP1, and the second signal wire TL2 may be located on another side of the pair of first sub-pixels SP1. The first signal wire TL1 may be electrically connected to the first electrode CE1 of one of the pair of first sub-pixels SP1, for example, the first electrode CE1 of the first-first sub-pixel SP1a. The second signal wire TL2 may be electrically connected to the first electrode CE1 of a remaining one of the pair of first sub-pixels SP1, for example, the first electrode CE1 of the first-second sub-pixel SP1b.

The third signal wire TL3 may be located on one side of the pair of second sub-pixels SP2, and the fourth signal wire TL4 may be located on another side of the pair of second sub-pixels SP2. For example, the third signal wire TL3 may be located adjacent to the second signal wire TL2. The third signal wire TL3 may be electrically connected to the first electrode CE1 of one of the pair of second sub-pixels SP2, for example, the first electrode CE1 of the second-first sub-pixel SP2a. The fourth signal wire TL4 may be electrically connected to the first electrode CE1 of a remaining one of the pair of second sub-pixels SP2, for example, the first electrode CE1 of the second-second sub-pixel SP2b.

The fifth signal wire TL5 may be located on one side of the pair of third sub-pixels SP3, and the sixth signal wire TL6 may be located on another side of the pair of third sub-pixels SP3. For example, the fifth signal wire TL5 may be located adjacent to the fourth signal wire TL4. The sixth signal wire TL6 may be located adjacent to the first signal wire TL1 that is connected to an adjacent pixel PX. The fifth signal wire TL5 may be electrically connected to the first electrode CE1 of one of the pair of third sub-pixels SP3, for example, the first electrode CE1 of the third-first sub-pixel SP3a. The sixth signal wire TL6 may be electrically connected to the first electrode CE1 of a remaining one of the pair of third sub-pixels SP3, for example, the first electrode CE1 of the third-second sub-pixel SP3b.

The plurality of signal wires TL may be formed of a conductive material. For example, the plurality of signal wires TL may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO); however, embodiments of the present specification are not limited thereto. In another example, the plurality of signal wires TL may have a multilayer structure of conductive materials. For example, the plurality of signal wires TL may have a multilayer structure including titanium (Ti)/aluminum (Al)/titanium (Ti)/indium tin oxide (ITO); however, embodiments of the present specification are not limited thereto.

A plurality of communication wires NL may be arranged in an area between the plurality of pixels PX. The plurality of communication wires NL may be arranged to extend in a row direction in the area between the plurality of pixels PX. The plurality of communication wires NL may be arranged in an area between the plurality of second electrodes CE2 and may not overlap the plurality of second electrodes CE2. For example, the plurality of communication wires NL may be wires used for short-range communication such as near field communication (NFC). The plurality of communication wires NL may function as an antenna. For example, the plurality of communication wires NL may be a plurality of connection wires or the like; however, embodiments of the present specification are not limited thereto.

According to the present specification, a bank BNK may be located in each of the plurality of sub-pixels. The plurality of banks BNK may be structures on which the plurality of light-emitting elements ED are seated. The plurality of banks BNK may guide the positions of the plurality of light-emitting elements ED during a transfer process of transferring the plurality of light-emitting elements ED to the display device 1000. During the transfer process of the plurality of light-emitting elements ED, the plurality of light-emitting elements ED may be transferred onto the plurality of banks BNK. The plurality of banks BNK may be a bank pattern, structure, or the like, but embodiments of the present specification are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated. Accordingly, the banks BNK of the first sub-pixel SP1, the second sub-pixel SP2, and the third sub-pixel SP3, onto which different types of light-emitting elements ED are transferred, may be easily identified.

The bank BNK of the first-first sub-pixel SP1a and the bank BNK of the first-second sub-pixel SP1b may be connected to each other or may be formed to be spaced apart or separated. For example, taking into account design factors such as transfer process requirements or the like, the bank BNK of the first-first sub-pixel SP1a and the bank BNK of the first-second sub-pixel SP1b, on which light-emitting elements ED of the same type are arranged, may be connected to each other, or may be spaced apart or separated. The bank BNK of the second-first sub-pixel SP2a and the bank BNK of the second-second sub-pixel SP2b may be connected to each other or may be formed to be spaced apart or separated. The bank BNK of the third-first sub-pixel SP3a and the bank BNK of the third-second sub-pixel SP3b may be connected to each other or may be formed to be spaced apart or separated. Accordingly, the banks BNK of the pair of first sub-pixels SP1, the banks BNK of the pair of second sub-pixels SP2, and the banks BNK of the pair of third sub-pixels SP3 may be formed in various ways, and embodiments of the present specification are not limited thereto.

For instance, the plurality of banks BNK may be formed of an organic insulating material. The plurality of banks BNK may be configured as a single-layer or multilayer structure using an organic insulating material. For example, the plurality of banks BNK may be formed of photoresist, polyimide (PI), an acrylic-based material, or the like, but embodiments of the present specification are not limited thereto.

The first electrode CE1 may be located in each of the plurality of sub-pixels. The first electrode CE1 may be located on the bank BNK. The first electrode CE1 may be electrically connected to one of the plurality of signal wires TL. At least a portion of the first electrode CE1 may extend outward from the bank BNK and may be electrically connected to the signal wire TL that is closest to the first electrode CE1. For example, a portion of the first electrode CE1 of the first-first sub-pixel SP1a may extend to one side area of the first-first sub-pixel SP1a and may be electrically connected to the first signal wire TL1. A portion of the first electrode CE1 of the first-second sub-pixel SP1b may extend to another side area of the first-second sub-pixel SP1b and may be electrically connected to the second signal wire TL2. A portion of the first electrode CE1 of the second-first sub-pixel SP2a may extend to one side area of the second-first sub-pixel SP2a and may be electrically connected to the third signal wire TL3. A portion of the first electrode CE1 of the second-second sub-pixel SP2b may extend to another side area of the second-second sub-pixel SP2b and may be electrically connected to the fourth signal wire TL4. A portion of the first electrode CE1 of the third-first sub-pixel SP3a may extend to one side area of the third-first sub-pixel SP3a and may be electrically connected to the fifth signal wire TL5. A portion of the first electrode CE1 of the third-second sub-pixel SP3b may extend to another side area of the third-second sub-pixel SP3b and may be electrically connected to the sixth signal wire TL6.

The first electrode CE1 may be electrically connected to the anode electrode 134 of the light-emitting element ED and may transmit an anode voltage from the pixel driving circuit PD to the light-emitting element ED through the signal wire TL. Different voltages may be applied to the first electrode CE1 of each of the plurality of sub-pixels depending on an image that is displayed. For example, different voltages may be applied to the respective first electrodes CE1 of the plurality of sub-pixels. Hence, each first electrode CE1 may serve as a pixel electrode; however, embodiments of the present specification are not limited thereto.

The first electrode CE1 may be formed of a conductive material. For example, the first electrode CE1 may be integrally formed with the plurality of signal wires TL. For instance, the first electrode CE1 may be formed of the same conductive material as the plurality of signal wires TL; however, embodiments of the present specification are not limited thereto. For instance, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but embodiments of the present specification are not limited thereto. In another example, the first electrode CE1 may be formed as a multilayer structure using conductive materials. For instance, the plurality of first electrodes CE1 may be configured as a multilayer structure including titanium (Ti)/aluminum (Al)/titanium (Ti)/indium tin oxide (ITO); however, embodiments of the present specification are not limited thereto.

The light-emitting element ED may be located in each of the plurality of sub-pixels. The plurality of light-emitting elements ED may each be either an LED or a micro LED; however, embodiments of the present specification are not limited thereto. The plurality of light-emitting elements ED may be arranged on the banks BNK and the first electrodes CE1. The plurality of light-emitting elements ED may be arranged on the first electrodes CE1 and may be electrically connected to the first electrodes CE1. Accordingly, each of the light-emitting elements ED may receive an anode voltage from the corresponding pixel driving circuit PD through the corresponding signal wire TL and the associated first electrode CE1, thereby emitting light.

The plurality of light-emitting elements ED may include a first light-emitting element 130, a second light-emitting element 140, and a third light-emitting element 150. The first light-emitting element 130 may be located in the first sub-pixel SP1. The second light-emitting element 140 may be located in the second sub-pixel SP2. The third light-emitting element 150 may be located in the third sub-pixel SP3. For example, any one of the first light-emitting element 130, the second light-emitting element 140, and the third light-emitting element 150 may be a red light-emitting element, another may be a green light-emitting element, and a remaining one may be a blue light-emitting element; however, embodiments of the present specification are not limited thereto. Accordingly, various colors of light, including white, may be implemented by combining the red light, green light, and blue light emitted from the plurality of light-emitting elements ED. The types of the plurality of light-emitting elements ED are illustrative, and embodiments of the present specification are not limited thereto.

The first light-emitting element 130 may include a first-first light-emitting element 130a located in the first-first sub-pixel SP1a, and a first-second light-emitting element 130b located in the first-second sub-pixel SP1b. The second light-emitting element 140 may include a second-first light-emitting element 140a located in the second-first sub-pixel SP2a, and a second-second light-emitting element 140b located in the second-second sub-pixel SP2b. The third light-emitting element 150 may include a third-first light-emitting element 150a located in the third-first sub-pixel SP3a, and a third-second light-emitting element 150b located in the third-second sub-pixel SP3b.

Referring to FIGS. 5, 6, and 7 together, the second electrode CE2 may be located in each of the plurality of sub-pixels. The second electrodes CE2 may be located on the corresponding light-emitting elements ED. The second electrodes CE2 may be electrically connected to the corresponding pixel driving circuits PD through a plurality of contact electrodes CCE.

For example, each second electrode CE2 may be electrically connected to a cathode electrode 135 (shown in FIG. 9) of the corresponding light-emitting element ED, and may transmit a cathode voltage from the pixel driving circuit PD to the light-emitting element ED. The same cathode voltage may be applied to the second electrode CE2 of each of the plurality of sub-pixels. For instance, the same voltage may be applied to the second electrode CE2 of each of the plurality of sub-pixels and the cathode electrode 135 of the light-emitting element ED. Accordingly, the second electrode CE2 may serve as a common electrode; however, embodiments of the present specification are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, at least some of the sub-pixels may share the second electrode CE2. For example, the second electrodes CE2 of at least some of the plurality of pixels PX that are arranged in the same row may be connected to each other. For instance, a single second electrode CE2 may be located for a plurality of pixels PX. A single second electrode CE2 may be arranged for every n sub-pixels.

For example, some of the respective second electrodes CE2 of the plurality of sub-pixels may be spaced apart or arranged separately from each other. For instance, the second electrode CE2 connected to the pixels PX that are in an nth row and the second electrode CE2 connected to the pixels PX that are in an (n+1)th row may be spaced apart or arranged separately from each other. For example, the plurality of second electrodes CE2 may be spaced apart from each other with a plurality of communication wires NL interposed therebetween and extending in a row direction. Accordingly, the number of the plurality of sub-pixels may be greater than the number of the plurality of second electrodes CE2. In another example, all of the second electrodes CE2 of the plurality of sub-pixels may be connected to each other such that only one second electrode CE2 is located on the substrate 110, and embodiments of the present specification are not limited thereto.

The plurality of second electrodes CE2 may be formed of a transparent conductive material; however, embodiments of the present specification are not limited thereto. The plurality of second electrodes CE2 may be made of a transparent conductive material, thus allowing light emitted from the light-emitting elements ED to be directed upward above the second electrodes CE2. For example, the second electrodes CE2 may be formed of a transparent conductive material such as indium tin oxide (ITO), indium zinc oxide (IZO), indium gallium zinc oxide (IGZO), or the like; however, embodiments of the present specification are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For instance, one second electrode CE2 may overlap a plurality of contact electrodes CCE.

For example, the plurality of contact electrodes CCE may be electrically connected to the plurality of second electrodes CE2. The plurality of contact electrodes CCE may be arranged between the substrate 110 and the plurality of second electrodes CE2 and may transmit a cathode voltage from the pixel driving circuits PD to the second electrodes CE2.

For example, in the case where a micro LED (or an inorganic light-emitting element) is used as the light-emitting element ED, the display device 1000 may be fabricated by forming a plurality of micro LEDs on a wafer and transferring the micro LEDs to the substrate 110 of the display device 1000. During the process of transferring the plurality of light-emitting elements ED, each having a micro-size, from the wafer to the substrate 110, various defects may occur. For instance, in some sub-pixels, a non-transfer defect may occur in which the light-emitting element ED is not successfully transferred. In other sub-pixels, a misalignment defect may occur in which the light-emitting element ED is transferred out of an intended position thereof due to alignment errors. Furthermore, even if the transfer process is normally performed, the transferred light-emitting element ED itself may be defective. Accordingly, taking into account defects that may occur during the transfer process of the plurality of light-emitting elements ED, a plurality of light-emitting elements ED of the same type may be transferred to each sub-pixel. A lighting inspection may be performed on the plurality of light-emitting elements ED, and ultimately, only the one light-emitting element ED that is determined to be normal may be used.

For example, both the first-first light-emitting element 130a and the first-second light-emitting element 130b may be transferred together onto a single pixel PX, and presence of defects thereof may be inspected. If both the first-first light-emitting element 130a and the first-second light-emitting element 130b are determined to be normal, only the first-first light-emitting element 130a may be used, while the first-second light-emitting element 130b may remain unused. In another example, if only the first-second light-emitting element 130b, among the first-first light-emitting element 130a and the first-second light-emitting element 130b, is determined to be normal, the first-first light-emitting element 130a may remain unused, and only the first-second light-emitting element 130b may be used. Accordingly, even if a plurality of light-emitting elements ED of the same type are transferred onto each pixel PX, ultimately, only one light-emitting element ED may be used.

Accordingly, any one of the pair of light-emitting elements ED may be a main (or primary) light-emitting element ED, and a remaining light-emitting element ED may be a redundancy light-emitting element ED. The redundancy light-emitting element ED may be an additional light-emitting element ED transferred as a backup in case of failure of the main light-emitting element ED. If the main light-emitting element ED is defective, the redundancy light-emitting element ED may be used as a replacement. Therefore, transferring the main and redundancy light-emitting elements ED together onto a single pixel PX may minimize the degradation in the display quality due to the defects occurring in the main light-emitting element ED and the redundancy light-emitting element ED.

For example, the first-first light-emitting element 130a, the second-first light-emitting element 140a, and the third-first light-emitting element 150a transferred onto each pixel PX may be used as main light-emitting elements ED. The first-second light-emitting element 130b, the second-second light-emitting element 140b, and the third-second light-emitting element 150b may be used as redundancy light-emitting elements ED.

The display panel 100 according to the present specification includes the first electrode CE1 located below the light-emitting element ED. The light output efficiency may be improved by exposing a portion of a conductive layer with relatively high reflectance among a plurality of conductive layers arranged in the first electrode CE1 through a process such as an etching process. However, during the process of fabricating the display panel 100, the exposed conductive layer of the first electrode CE1 may be exposed to solutions used in various processes, which may cause corrosion or damage to the exposed conductive layer. For example, aluminum included in the first electrode CE1 may be easily corroded when exposed to a solution such as tetramethylammonium hydroxide (TMAH).

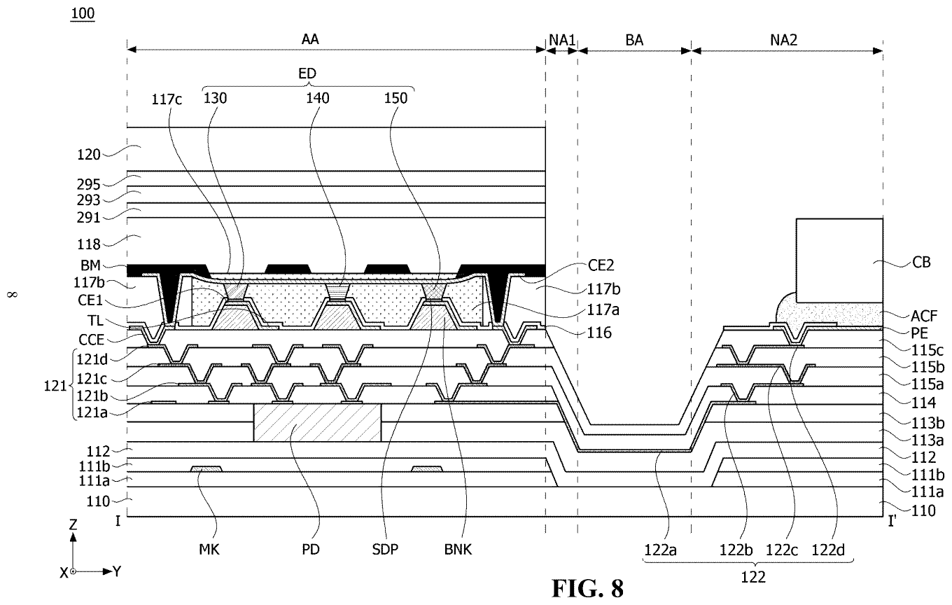

FIG. 8 is a sectional view illustrating a display panel of the display device taken along line I-I′ of FIG. 3 according to an embodiment of the present specification. Here, the display panel illustrated in FIG. 8 may be a display panel 100 according to a first embodiment. For example, FIG. 8 is a sectional view illustrating the display area AA, the first non-display area NA1, the bending area BA, and the second non-display area NA2, taken along line I-I′ of FIG. 3.

Referring to FIG. 8, a first buffer layer 111a and a second buffer layer 111b may be arranged in a remaining area of the substrate 110 except for the bending area BA.

The first buffer layer 111a and the second buffer layer 111b may be located in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be formed of an inorganic insulating material. For example, the first buffer layer 111a and the second buffer layer 111b may be configured as a single-layer or multilayer structure formed of silicon oxide (SiOx) or silicon nitride (SiNx); however, embodiments of the present specification are not limited thereto.

For example, a portion of the first buffer layer 111a and a portion of the second buffer layer 111b in the bending area BA may be removed. An upper surface of the substrate 110 located in the bending area BA may be exposed from the first buffer layer 111a and the second buffer layer 111b. Cracks that may occur in the first buffer layer 111a and the second buffer layer 111b during bending may be minimized by removing the first buffer layer 111a and the second buffer layer 111b, which are formed of an inorganic insulating material, from the bending area BA.

A plurality of alignment keys MK may be arranged between the first buffer layer 111a and the second buffer layer 111b. The plurality of alignment keys MK may be configured to identify the position of the pixel driving circuit PD during the process of fabricating the display device 1000. For example, the plurality of alignment keys MK may be configured to align the position of the pixel driving circuit PD, which is transferred onto a circuit adhesive layer 112. In another example, the plurality of alignment keys MK may be omitted.

The circuit adhesive layer 112 may be located on the second buffer layer 111b. The circuit adhesive layer 112 may be located in the display area AA, the first non-display area NA1, the bending area BA, and the second non-display area NA2. In another example, at least a portion of the circuit adhesive layer 112 in the non-display area NA, including the bending area BA, may be removed. For example, the circuit adhesive layer 112 may be formed of any one of an adhesive polymer, epoxy resin, UV-curable resin, a polyimide-based material, an acrylate-based material, a urethane-based material, or polydimethylsiloxane (PDMS); however, embodiments of the present specification are not limited thereto.

In the display area AA, the pixel driving circuit PD may be located on the circuit adhesive layer 112. In the case where the pixel driving circuit PD is implemented as a driver, the driver may be mounted on the circuit adhesive layer 112 through a transfer process; however, embodiments of the present specification are not limited thereto.

A first protective layer 113a and a second protective layer 113b may be arranged on the circuit adhesive layer 112 and the pixel driving circuit PD. The first protective layer 113a and the second protective layer 113b may be arranged to enclose side surfaces of the pixel driving circuit PD. However, embodiments of the present specification are not limited thereto. For example, the second protective layer 113b may be located to cover at least a portion of an upper surface of the pixel driving circuit PD. For example, at least one of the first protective layer 113a and the second protective layer 113b located in the bending area BA may be omitted. For instance, the first protective layer 113a may be provided throughout the display area AA and the non-display area NA, and the second protective layer 113b may be partially provided in the display area AA, the first non-display area NA1, and the second non-display area NA2. For example, a portion of the second protective layer 113b in the bending area BA may be removed; however, embodiments of the present specification are not limited thereto.

The first protective layer 113a and the second protective layer 113b may be formed of an organic insulating material. However, embodiments of the present specification are not limited thereto. For example, the first protective layer 113a and the second protective layer 113b may be formed of photoresist, polyimide (PI), a photoacrylic-based material, or the like. However, embodiments of the present specification are not limited thereto. For instance, the first protective layer 113a and the second protective layer 113b may each be an overcoating layer or an insulating layer; however, embodiments of the present specification are not limited thereto.

According to the present specification, a plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected to the plurality of signal wires TL and the plurality of contact electrodes CCE through the plurality of first connection wires 121. For instance, the plurality of first connection wires 121 may include a first-first connection wire 121a, a first-second connection wire 121b, a first-3 connection wire 121c, and a first-4 connection wire 121d; however, embodiments of the present specification are not limited thereto.

For example, the plurality of first-first connection wires 121a may be arranged on the second protective layer 113b. The plurality of first-first connection wires 121a may be electrically connected to the pixel driving circuit PD. The plurality of first-first connection wires 121a may transmit a voltage output from the pixel driving circuit PD to the first electrode CE1 or the second electrode CE2.

For instance, a third protective layer 114 may be located on the second protective layer 113b. The third protective layer 114 may be provided throughout the display area AA and the non-display area NA. In the bending area BA, the third protective layer 114 may cover or enclose a side surface of the second protective layer 113b and an upper surface of the first protective layer 113a. The third protective layer 114 may be formed of an organic insulating material. For example, the third protective layer 114 may be formed of photoresist, polyimide (PI), a photoacrylic-based material, or the like; however, embodiments of the present specification are not limited thereto. For example, the first protective layer 113a, the second protective layer 113b, and the third protective layer 114 may be formed of the same material; however, embodiments of the present specification are not limited thereto. For example, the first protective layer 113a, the second protective layer 113b, and the third protective layer 114 may each be an insulating layer; however, embodiments of the present specification are not limited thereto.

A plurality of first-second connection wires 121b may be arranged on the third protective layer 114. The plurality of first-second connection wires 121b may be connected to or directly connected to the pixel driving circuit PD. For example, some of the plurality of first-second connection wires 121b may be directly connected to the pixel driving circuit PD through a contact hole of the third protective layer 114. Some others of the first-second connection wires 121b may be electrically connected to the first-first connection wire 121a through a contact hole of the third protective layer 114. However, embodiments of the present specification are not limited thereto. A voltage output from the pixel driving circuit PD may be transmitted to the first electrode CE1 or the second electrode CE2 through the plurality of first-second connection wires 121b and other connection wires.

A first insulating layer 115a may be located on a plurality of first-second connection wires 121b. The first insulating layer 115a may be provided throughout the display area AA and the non-display area NA; however, embodiments of the present specification are not limited thereto. The first insulating layer 115a may be formed of an organic insulating material; however, embodiments of the present specification are not limited thereto. For example, the first insulating layer 115a may be formed of photoresist, polyimide (PI), a photoacrylic-based material, or the like; however, embodiments of the present specification are not limited thereto.

A plurality of first-3 connection wires 121c may be arranged on the first insulating layer 115a. The plurality of first-3 connection wires 121c may be electrically connected to the plurality of first-second connection wires 121b. For example, the first-3 connection wires 121c may be electrically connected to the first-second connection wires 121b through a contact hole of the first insulating layer 115a.

A second insulating layer 115b may be located on the plurality of first-3 connection wires 121c. The second insulating layer 115b may be provided in a remaining area except for the bending area BA; however, embodiments of the present specification are not limited thereto. The second insulating layer 115b may be located in the display area AA, the first non-display area NA1, and the second non-display area NA2; however, embodiments of the present specification are not limited thereto. For example, a portion of the second insulating layer 115b that is located in the bending area BA may be removed. The second insulating layer 115b may be formed of an organic insulating material; however, embodiments of the present specification are not limited thereto. For example, the second insulating layer 115b may be formed of photoresist, polyimide (PI), a photoacrylic-based material, or the like; however, embodiments of the present specification are not limited thereto.

A plurality of first-4 connection wires 121d may be arranged on the second insulating layer 115b. The plurality of first-4 connection wires 121d may be electrically connected to the plurality of first-3 connection wires 121c. For example, the first-4 connection wires 121d may be electrically connected to the first-3 connection wires 121c through a contact hole of the second insulating layer 115b.

According to the present specification, a plurality of second connection wires 122 may be arranged on the second protective layer 113b in the non-display area NA. The plurality of second connection wires 122 may be wires provided to transmit, to the pixel driving circuit PD in the display area AA, signals that are transmitted from the flexible circuit board (or flexible film) CB and the printed circuit board 160 (see FIG. 1) to the pad portion PAD. For example, the plurality of second connection wires 122 may be electrically connected to the plurality of pad electrodes PE and may receive signals from the flexible circuit board (or flexible film) CB and the printed circuit board.

For example, the plurality of second connection wires 122 may extend from the pad portion PAD toward the display area AA and transmit signals to the wires in the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d.

A plurality of second-first connection wires 122a may be arranged on the second protective layer 113b. The plurality of second-first connection wires 122a may extend from the second non-display area NA2 to the bending area BA and the first non-display area NA1. The plurality of second-first connection wires 122a may transmit, to the pixel driving circuit PD in the display area AA, signals that are transmitted from the flexible circuit board (or flexible film) CB and the printed circuit board to the pad portion PAD.

A plurality of second-second connection wires 122b may be arranged on the third protective layer 114. The plurality of second-second connection wires 122b may be arranged in the second non-display area NA2. The second-second connection wires 122b may be electrically connected to the second-first connection wires 122a through a contact hole of the third protective layer 114. Accordingly, signals from the flexible circuit board (or flexible film) CB and the printed circuit board may be transmitted to the second-first connection wires 122a through the second-second connection wires 122b.

A plurality of second-third connection wires 122c may be arranged on the first insulating layer 115a. The second-third connection wires 122c may be located in the second non-display area NA2. The second-third connection wires 122c may be electrically connected to the second-second connection wires 122b through a contact hole of the first insulating layer 115a. Accordingly, signals from the flexible circuit board (or flexible film) CB and the printed circuit board may be transmitted to the second-first connection wires 122a through the second-third connection wires 122c and the second-second connection wires 122b.

A plurality of second-fourth connection wires 122d may be arranged on the second insulating layer 115b. The second-fourth connection wires 122d may be located in the second non-display area NA2. The second-fourth connection wires 122d may be electrically connected to the second-third connection wires 122c through a contact hole of the second insulating layer 115b. Accordingly, signals from the at least one flexible circuit board (or flexible film) CB and the printed circuit board may be transmitted to the second-first connection wires 122a through the second-fourth connection wires 122d, the second-third connection wires 122c, and the second-second connection wires 122b.

The plurality of first connection wires 121 and the plurality of second connection wires 122 may be formed of either a highly flexible conductive material or any one of various conductive materials applicable to the display area AA. For example, the second connection wires 122, a portion of which is located in the bending area BA, may be formed of a highly flexible conductive material such as gold (Au), silver (Ag), aluminum (Al), or the like; however, embodiments of the present specification are not limited thereto. In another example, the plurality of first connection wires 121 and the plurality of second connection wires 122 may be formed of molybdenum (Mo), chromium (Cr), titanium (Ti), nickel (Ni), neodymium (Nd), copper (Cu), an alloy of silver (Ag) and magnesium (Mg), or other alloys thereof. However, embodiments of the present specification are not limited thereto.

A third insulating layer 115c may be located on the plurality of first connection wires 121 and the plurality of second connection wires 122. The third insulating layer 115c may be located in a remaining area except for the bending area BA; however, embodiments of the present specification are not limited thereto. The third insulating layer 115c may be located in the display area AA, the first non-display area NA1, and the second non-display area NA2. A portion of the third insulating layer 115c in the bending area BA may be removed. The third insulating layer 115c may be formed of an organic insulating material, but embodiments of the present specification are not limited thereto. For example, the third insulating layer 115c may be formed of photoresist, polyimide (PI), a photoacrylic-based material, or the like; however, embodiments of the present specification are not limited thereto.

In the display area AA, the plurality of banks BNK may be arranged on the third insulating layer 115c. The plurality of banks BNK may be arranged to respectively overlap the plurality of sub-pixels. One or more light-emitting elements ED of the same type may be located over each of the plurality of banks BNK.

In the display area AA, the plurality of signal wires TL may be arranged on the third insulating layer 115c. The plurality of signal wires TL may be located in areas between the plurality of banks BNK. For example, the plurality of signal wires TL may be located adjacent to any one of the plurality of banks BNK.

In the display area AA, the plurality of contact electrodes CCE may be arranged on the third insulating layer 115c. The plurality of contact electrodes CCE may each supply a cathode voltage from the pixel driving circuit PD to the corresponding second electrode CE2.

The first electrodes CE1 may each be located on the corresponding bank BNK. For example, the first electrode CE1 may be provided to extend from an adjacent signal wire TL toward an upper portion of the bank BNK. The first electrode CE1 may be formed on both an upper surface and a side surface of the bank BNK. For example, the first electrode CE1 may be provided to extend from the signal wire TL on an upper surface of the third insulating layer 115c to the side surface and the upper surface of the bank BNK.

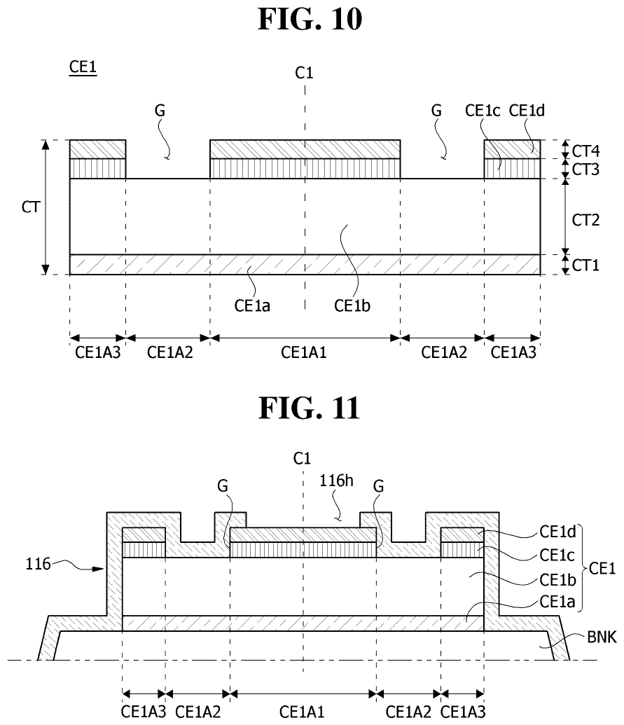

FIG. 9 is a partial sectional view illustrating a subpixel of the display device according to an embodiment of the present specification. FIG. 9 is a partial sectional view illustrating a sub-pixel including a light-emitting element located in the display area AA. FIG. 10 is a diagram illustrating the first electrode of the display device according to an embodiment of the present specification. FIG. 11 is a diagram illustrating an arrangement relationship between the first electrode and a passivation layer of the display device according to an embodiment of the present specification.

Referring to FIGS. 9 to 11, the first electrode CE1 may be configured with a plurality of conductive layers. For example, the first electrode CE1 may include a first conductive layer CE1a, a second conductive layer CE1b, a third conductive layer CE1c, and a fourth conductive layer CE1d. However, embodiments of the present specification are not limited thereto.

The first conductive layer CE1a may be located on the bank BNK. The second conductive layer CE1b may be located on the first conductive layer CE1a. The third conductive layer CE1c may be located on the second conductive layer CE1b. The fourth conductive layer CE1d may be located on the third conductive layer CE1c. For example, each of the first conductive layer CE1a, the second conductive layer CE1b, the third conductive layer CE1c, and the fourth conductive layer CE1d may be formed of at least one of titanium (Ti), molybdenum (Mo), aluminum (Al), or indium tin oxide (ITO). However, embodiments of the present specification are not limited thereto.

According to the present specification, some conductive layers with high reflection efficiency among the plurality of conductive layers forming the first electrode CE1 may be configured as alignment keys and/or reflectors for aligning the light-emitting element ED. For example, the second conductive layer CE1b among the plurality of conductive layers of the first electrode CE1 may include a reflective material. For instance, the second conductive layer CE1b may include aluminum (Al), but embodiments of the present specification are not limited thereto. Accordingly, the second conductive layer CE1b may be configured as a reflector. Furthermore, the high reflection efficiency of the second conductive layer CE1b may facilitate identification thereof in the manufacturing process. Hence, the position or transfer position of the light-emitting element ED may be aligned based on the second conductive layer CE1b.

For example, to configure the second conductive layer CE1b as a reflector, the third conductive layer CE1c and the fourth conductive layer CE1d that cover the second conductive layer CE1b may be partially removed or etched. For instance, the upper surface of the second conductive layer CE1b may be exposed by removing or etching a portion of the third conductive layer CE1c and a portion of the fourth conductive layer CE1d. For example, except for central portions where a solder pattern SDP is located and perimeter portions (or edge portions) of the third conductive layer CE1c and the fourth conductive layer CE1d, remaining portions may be removed. For instance, the perimeter portion (or edge portion) of each of the third conductive layer CE1c, which is formed of titanium (Ti), and the fourth conductive layer CE1d, which is formed of indium tin oxide (ITO), may remain unetched. Accordingly, in a mask process for forming the first electrode CE1, other conductive layers such as the second conductive layer CE1b of the first electrode CE1 may be protected from corrosion caused by a tetramethylammonium hydroxide (TMAH) solution used in the mask process.

According to the present specification, the first conductive layer CE1a and the third conductive layer CE1c may each include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has excellent adhesion to a solder pattern SDP and exhibits corrosion resistance and acid resistance. However, embodiments of the present specification are not limited thereto.

The first conductive layer CE1a, the second conductive layer CE1b, the third conductive layer CE1c, and the fourth conductive layer CE1d may be sequentially deposited and patterned through a photolithography process and an etching process. However, embodiments of the present specification are not limited thereto.

Referring to FIG. 10, the first electrode CE1 may include the first conductive layer CE1a, the second conductive layer CE1b located on the first conductive layer CE1a, the third conductive layer CE1c located on the second conductive layer CE1b, and the fourth conductive layer CE1d located on the third conductive layer CE1c. The second conductive layer CE1b may be formed of a material having a higher light reflectance than the third conductive layer CE1c and the fourth conductive layer CE1d. For example, the second conductive layer CE1b may include aluminum (Al) or silver (Ag). Accordingly, in the display panel 100 according to the present specification, the second conductive layer CE1b, which has a higher light reflectance than the fourth conductive layer CE1d that is in contact with the solder pattern SDP, may be exposed, thereby improving the light output efficiency of the light-emitting element ED by reflecting light emitted from the light-emitting element ED using the second conductive layer CE1b.

The first electrode CE1 may include a groove G. For example, the first electrode CE1 may include the groove G formed in an upper surface of the first electrode CE1. For example, the first electrode CE1 may include the groove G that is formed as a concave shape in the upper surface of the first electrode CE1. The groove G may be formed along the perimeter of the first electrode CE1 and may be arranged to be spaced apart from an edge of the upper surface of the first electrode CE1. The groove G may be formed in the upper surface of the first electrode CE1 through a photolithography process and an etching process; however, embodiments of the present specification are not limited thereto.

A portion of the upper surface of the second conductive layer CE1b may be exposed by the groove G, and the exposed portion of the second conductive layer CE1b may reflect light, which is emitted by the light-emitting element ED and incident on the second conductive layer CE1b through the groove G, thereby improving the light output efficiency of the display device 1000.

As the groove G is formed, the first electrode CE1 may include a first electrode area CE1A1, with which the solder pattern SDP is in contact, a second electrode area CE1A2 located outside the first electrode area CE1A1, and a third electrode area CE1A3 located outside the second electrode area CE1A2. The second electrode area CE1A2 may be an area of the second conductive layer CE1b on which the third conductive layer CE1c and the fourth conductive layer CE1d are not located. The second electrode area CE1A2 may serve as a reflective area that enhances the light output efficiency by reflecting light incident on the second conductive layer CE1b through the groove G.

Although in FIG. 10 the first electrode CE1 is illustrated as including the first electrode area CE1A1, the second electrode area CE1A2, and the third electrode area CE1A3, embodiments of the present specification are not limited thereto. For example, to improve the light output efficiency of the display panel 100, the third electrode area CE1A3 may be omitted. For instance, the first electrode CE1 may include only the first electrode area CE1A1 and the second electrode area CE1A2.

The first electrode CE1 may be formed to have a preset thickness CT. Since the first electrode CE1 may be formed using a plurality of conductive layers with different resistances, even if the design specifications for the resistance of the first electrode CE1 change, the resistance of the first electrode CE1 may be adjusted by controlling the thicknesses of the conductive layers. The thickness of each conductive layer may refer to a distance between one surface and the other surface of the conductive layer arranged in a Z-axis direction.

The first conductive layer CE1a may be formed to have a first thickness CT1. The first thickness CT1 may be adjustable. The first conductive layer CE1a may have a lower light reflectance and a higher resistance than the second conductive layer CE1b. For example, the first conductive layer CE1a may include titanium (Ti) or molybdenum (Mo); however, embodiments of the present specification are not limited thereto.

The second conductive layer CE1b may be formed to have a second thickness CT2 greater than the first thickness CT1. The second thickness CT2 may be adjustable. The second conductive layer CE1b may be formed of a material with a higher light reflectance than the third conductive layer CE1c and the fourth conductive layer CE1d. For example, the second conductive layer CE1b may include aluminum (Al) or silver (Ag); however, embodiments of the present specification are not limited thereto.

The third conductive layer CE1c may be formed to have a third thickness CT3. The third thickness CT3 may be adjustable. The third conductive layer CE1c may be formed of a material with a lower light reflectance and a higher resistance than the second conductive layer CE1b. For example, the third conductive layer CE1c may include titanium (Ti) or molybdenum (Mo); however, embodiments of the present specification are not limited thereto.

The fourth conductive layer CE1d may be formed to have a fourth thickness CT4. The fourth thickness CT4 may be adjustable. The fourth conductive layer CE1d may be formed of a material with a lower light reflectance than the second conductive layer CE1b. For example, the fourth conductive layer CE1d may include a transparent conductive oxide, such as indium tin oxide (ITO) or indium zinc oxide (IZO), which has excellent adhesion to the solder pattern SDP and exhibits corrosion resistance and acid resistance. However, embodiments of the present specification are not limited thereto.

The thicknesses of the third conductive layer CE1c and the fourth conductive layer CE1d may be determined, taking into account the reflection efficiency depending on the depth of the groove G. Even when the first electrode CE1 is configured to have a preset thickness CT, the display panel 100 according to the present specification may achieve the desired resistance of the first electrode CE1 by adjusting the thicknesses of the first conductive layer CE1a and the second conductive layer CE1b.

According to the present specification, the signal wire TL, the contact electrode CCE, and the pad electrode PE that are arranged in the same layer as the first electrode CE1 may be configured as a multilayer structure formed of a conductive material. However, embodiments of the present specification are not limited thereto. For example, the signal wire TL, the contact electrode CCE, and the pad electrode PE may be formed as a multilayer structure including indium tin oxide (ITO)/titanium (Ti)/aluminum (Al)/titanium (Ti). However, embodiments of the present specification are not limited thereto.

According to the present specification, the solder pattern SDP may be located on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP; however, embodiments of the present specification are not limited thereto. For example, the first electrode CE1 and the anode electrode 134 of the light-emitting element ED may be electrically connected through eutectic bonding using the solder pattern SDP; however, embodiments of the present specification are not limited thereto. For instance, in the case where the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. Through eutectic bonding, the light-emitting element ED may be bonded to the solder pattern SDP and the first electrode CE1 without the need for additional adhesive material. For example, the solder pattern SDP may be formed of indium (In), tin (Sn), or an alloy thereof; however, embodiments of the present specification are not limited thereto. For instance, the solder pattern SDP may be a pattern, a pattern layer, a bonding pad, or a junction pad, but embodiments of the present specification are not limited thereto.

According to the present specification, a passivation layer 116 may be located on the plurality of signal wires TL, the plurality of first electrodes CE1, the plurality of contact electrodes CCE, and the third insulating layer 115c. For example, the passivation layer 116 may be located in the display area AA, the first non-display area NA1, and the second non-display area NA2. A portion of the passivation layer 116 that is located in the bending area BA may be removed. A portion of the passivation layer 116 that covers the plurality of pad electrodes PE in the second non-display area NA2 may also be removed. Because the passivation layer 116 is located to cover areas other than areas where the bending area BA, the plurality of pad electrodes PE and the solder pattern SDP are located, the penetration of moisture or impurities into the light-emitting element ED may be reduced. For example, the passivation layer 116 may be configured as a single-layer or multilayer structure including silicon oxide (SiOx) or silicon nitride (SiNx). However, embodiments of the present specification are not limited thereto. For instance, the passivation layer 116 may function as a protective layer or an insulating layer, but embodiments of the present specification are not limited thereto. For example, the passivation layer 116 may include a hole 116H in each of the plurality of sub-pixels, in which the solder pattern SDP is located and exposed. According to the present specification, the passivation layer 116 may include a plurality of holes 116H and a plurality of solder patterns SDP are located in the plurality of holes 116H.

The passivation layer 116 may be located to cover the groove G of the first electrode CE1, thereby protecting the exposed second conductive layer CE1b. For example, to form the solder pattern SDP, an organic insulating material, which may be used as a mask, may be deposited on the passivation layer 116. Thereafter, a hole corresponding to the formation position of the solder pattern SDP may be formed in the organic insulating material by performing an exposure process and an etching process of removing, using an etching solution, a portion of the organic insulating material that has reacted to the exposure process. Subsequently, a material for forming the solder pattern SDP may be placed inside the hole, thereby forming the solder pattern SDP on the first electrode CE1. The organic insulating material used as the mask may then be removed through a mask removal process. If the position at which the organic insulating material is exposed deviates from a preset position, an upper portion of the second conductive layer CE1b exposed to a developing solution used in the exposure process may become exposed, causing damage to the second conductive layer CE1b. However, in the display panel 100 according to the present specification, the passivation layer 116 may prevent or at least reduce such damage to the second conductive layer CE1b in advance. Accordingly, in the display panel 100 according to the present specification, the passivation layer 116 may enhance the reliability of the manufacturing process.

The passivation layer 116, which extends toward an inside of the first electrode CE1 from an upper edge of the first electrode CE1, may be located to cover the groove G, thereby protecting the exposed second conductive layer CE1b. An end of the passivation layer 116 that extends toward the inside of the first electrode CE1 on the upper surface of the first electrode CE1 may overlap the edge of the first electrode area CE1A1 in the Z-axis direction. The inward direction of the first electrode CE1 may refer to a direction toward an electrode center C1 of the first electrode CE1. An outward direction of the first electrode CE1 may refer to a direction opposite to the inward direction of the first electrode CE1. The center C1 of the first electrode CE1 may be the center of the first electrode CE1 in a horizontal plane extending in the X-axis and Y-axis directions. Furthermore, the end of the passivation layer 116 that extends inwardly on the upper surface of the first electrode CE1 may be an inner end of the passivation layer 116.

In each of the plurality of sub-pixels, the light-emitting element ED may be located on the solder pattern SDP. A first light-emitting element 130 may be located in a first sub-pixel SP1. A second light-emitting element 140 may be located in a second sub-pixel SP2. A third light-emitting element 150 may be located in a third sub-pixel SP3.

The light-emitting element ED may be formed on a silicon wafer by a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like. However, embodiments of the present specification are not limited thereto.

Referring to FIG. 9, the first light-emitting element 130 may include an anode electrode 134, a first semiconductor layer 131, an active layer 132, a second semiconductor layer 133, a cathode electrode 135, and an encapsulation film 136. However, embodiments of the present specification are not limited thereto. For example, the first light-emitting element 130 may not include the encapsulation film 136.

The first semiconductor layer 131 may be located on the solder pattern SDP. The second semiconductor layer 133 may be located on the first semiconductor layer 131.

For example, either the first semiconductor layer 131 or the second semiconductor layer 133 may be implemented with a compound semiconductor such as a III-V group or II-VI group semiconductor, or the like, and may be doped with an impurity (or dopant). For instance, either the first semiconductor layer 131 or the second semiconductor layer 133 may be an n-type doped semiconductor layer, and the other may be a p-type doped semiconductor layer. However, embodiments of the present specification are not limited thereto. For example, at least one of the first semiconductor layer 131 and the second semiconductor layer 133 may be a layer formed by doping a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), with an n-type or p-type impurity. However, embodiments of the present specification are not limited thereto. For example, the n-type impurity may include silicon (Si), germanium (Ge), selenium (Se), carbon (C), tellurium (Te), or tin (Sn); however, embodiments of the present specification are not limited thereto. For example, the p-type impurity may include magnesium (Mg), zinc (Zn), calcium (Ca), strontium (Sr), barium (Ba), beryllium (Be), or the like, but embodiments of the present specification are not limited thereto.

For example, the first semiconductor layer 131 and the second semiconductor layer 133 may be respectively formed of a nitride semiconductor including an n-type impurity and a nitride semiconductor including a p-type impurity. However, embodiments of the present specification are not limited thereto. For instance, the first semiconductor layer 131 may be a nitride semiconductor including a p-type impurity, and the second semiconductor layer 133 may be a nitride semiconductor including an n-type impurity; however, embodiments of the present specification are not limited thereto.

The active layer 132 may be located between the first semiconductor layer 131 and the second semiconductor layer 133. The active layer 132 may receive holes and electrons from the first semiconductor layer 131 and the second semiconductor layer 133 and emit light. For example, the active layer 132 may be formed in one of a single well structure, a multiple well structure, a single quantum well structure, a multi-quantum well (MQW) structure, a quantum dot structure, or a quantum wire structure. However, embodiments of the present specification are not limited thereto. For instance, the active layer 132 may be formed of indium gallium nitride (InGaN), gallium nitride (GaN), or the like; however, embodiments of the present specification are not limited thereto.

In another example, the active layer 132 may include a multi-quantum well (MQW) structure having a well layer and a barrier layer with a higher band gap than the well layer. For instance, the active layer 132 may be configured with a well layer formed of InGaN and a barrier layer formed of AlGaN. However, embodiments of the present specification are not limited thereto.

The anode electrode 134 may be located between the first semiconductor layer 131 and the solder pattern SDP. For example, the anode electrode 134 may electrically connect the first semiconductor layer 131 and the first electrode CE1. An anode voltage output from the pixel driving circuit PD may be applied to the first semiconductor layer 131 through the signal wire TL, the first electrode CE1, and the anode electrode 134. For instance, the anode electrode 134 may be formed of a conductive material capable of eutectic bonding with the solder pattern SDP; however, embodiments of the present specification are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, embodiments of the present specification are not limited thereto.

The cathode electrode 135 may be located on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material to allow light emitted from the light-emitting element ED to pass upward above the light-emitting element ED. However, embodiments of the present specification are not limited thereto. For instance, the cathode electrode 135 may be formed of a material such as indium tin oxide (ITO), indium zinc oxide (IZO), indium gallium zinc oxide (IGZO), or the like; however, embodiments of the present specification are not limited thereto.

The encapsulation film 136 may be located on at least a portion of the first semiconductor layer 131, the active layer 132, the second semiconductor layer 133, the anode electrode 134, and the cathode electrode 135. For example, the encapsulation film 136 may enclose at least a portion of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For instance, the encapsulation film 136 may be located on a side surface of the first semiconductor layer 131, a side surface of the active layer 132, and a side surface of the second semiconductor layer 133.

For example, the encapsulation film 136 may be located on at least a portion of the anode electrode 134 and the cathode electrode 135, e.g., an edge portion (or peripheral portion or one side) of the anode electrode 134 and an edge portion (or peripheral portion or one side) of the cathode electrode 135. At least a portion of the anode electrode 134 may be exposed from the encapsulation film 136, allowing the anode electrode 134 to be connected to the solder pattern SDP. For instance, at least a portion of the cathode electrode 135 may be exposed from the encapsulation layer 136, allowing the cathode electrode 135 to be connected to the second electrode CE2. For example, the encapsulation film 136 may be formed of an insulating material such as silicon nitride (SiNx) or silicon oxide (SiOx); however, embodiments of the present specification are not limited thereto.

In another example, the encapsulation film 136 may have a structure in which a reflective material is dispersed in a resin layer. However, embodiments of the present specification are not limited thereto. For example, the encapsulation film 136 may be formed as a reflector with various structures. However, embodiments of the present specification are not limited thereto. The encapsulation film 136 may reflect light, which is emitted from the active layer 132, upward, thereby improving light extraction efficiency. For instance, the encapsulation film 136 may be a reflective layer; however, embodiments of the present specification are not limited thereto.

According to the present specification, although the light-emitting element ED has been described with a vertical structure, embodiments of the present specification are not limited thereto. For example, the light-emitting element ED may have a lateral structure or a flip-chip structure. The light-emitting element ED may be an inorganic light-emitting element, but embodiments of the present specification are not limited thereto.

Although the first light-emitting element 130 has been described with reference to FIG. 9, the second light-emitting element 140 and the third light-emitting element 150 may have substantially the same structure as the first light-emitting element 130. For example, the second light-emitting element 140 and the third light-emitting element 150 may have substantially the same components as the first light-emitting element 130, including the first semiconductor layer 131, the active layer 132, the second semiconductor layer 133, the anode electrode 134, the cathode electrode 135, and the encapsulation film 136.

According to the present specification, a first optical layer 117a may be located around the plurality of light-emitting elements ED in the display area AA. The first optical layer 117a may enclose the plurality of light-emitting elements ED. For example, the first optical layer 117a may be formed to cover the plurality of light-emitting elements ED and the banks BNK in the respective areas of the plurality of sub-pixels. For instance, the first optical layer 117a may cover the banks BNK, a portion of the passivation layer 116, and spaces between the plurality of light-emitting elements ED. The first optical layer 117a may be located between or cover the spaces between the plurality of light-emitting elements ED included in each pixel PX and the spaces between the plurality of banks BNK. For instance, the first optical layer 117a may extend in a first direction (X-axis direction) and have spacing in a second direction (Y-axis direction). For example, the first optical layer 117a may be formed to enclose the side surfaces of the light-emitting elements ED and the banks BNK between the passivation layer 116 and the second electrode CE2. However, embodiments of the present specification are not limited thereto. For instance, the first optical layer 117a may be a diffusion layer or a sidewall diffusion layer, but embodiments of the present specification are not limited thereto.

The first optical layer 117a may include an organic insulating material in which fine particles are dispersed. However, embodiments of the present specification are not limited thereto. For example, the first optical layer 117a may be formed of siloxane in which fine metal particles, such as titanium dioxide (TiO₂) particles, are dispersed, but embodiments of the present specification are not limited thereto. Light emitted from the plurality of light-emitting elements ED may be scattered by the fine particles dispersed in the first optical layer 117a and then emitted to the outside of the display device 1000. Accordingly, the first optical layer 117a may enhance the extraction efficiency of the light emitted from the plurality of light-emitting elements ED.

For example, the first optical layer 117a may be located in each of the plurality of pixels PX or may be located in some pixels PX that are arranged in the same row. However, embodiments of the present specification are not limited thereto. For example, the first optical layer 117a may be provided in each of the plurality of pixels PX, or the plurality of pixels PX may share a single first optical layer 117a. In another example, each of the plurality of sub-pixels may separately include the first optical layer 117a, but embodiments of the present specification are not limited thereto.

According to the present specification, a second optical layer 117b may be located on the passivation layer 116 in the display area AA. For example, the second optical layer 117b may be located around the first optical layer 117a. For example, the second optical layer 117b may be formed to enclose the first optical layer 117a. For instance, the second optical layer 117b may be in contact with a side surface of the first optical layer 117a. For example, the second optical layer 117b may be located in an area between the plurality of pixels PX; however, embodiments of the present specification are not limited thereto. For example, the second optical layer 117b may be a diffusion layer, a diffusion layer window, a window diffusion layer, or the like, but embodiments of the present specification are not limited thereto.

The second optical layer 117b may be formed of an organic insulating material; however, embodiments of the present specification are not limited thereto. The second optical layer 117b may be formed of the same material as the first optical layer 117a; however, embodiments of the present specification are not limited thereto. For example, the first optical layer 117a may include fine particles, and the second optical layer 117b may not include fine particles. For example, the second optical layer 117b may be formed of siloxane; however, embodiments of the present specification are not limited thereto.

For example, the thickness of the first optical layer 117a may be smaller than that of the second optical layer 117b, but embodiments of the present specification are not limited thereto. Accordingly, in a plan view, the area where the first optical layer 117a is located may include a concave portion that is recessed inward relative to an upper surface of the second optical layer 117b.

According to the present specification, the second electrode CE2 may be located on the first optical layer 117a and the second optical layer 117b. For example, the second electrode CE2 may be electrically connected to the plurality of contact electrodes CCE through a contact hole of the second optical layer 117b. For example, the second electrode CE2 may be located on the plurality of light-emitting elements ED. For instance, the second electrode CE2 may include a transparent conductive oxide such as indium tin oxide (ITO) or indium zinc oxide (IZO); however, embodiments of the present specification are not limited thereto. For example, the second electrode CE2 may be located in contact with the cathode electrode 135. For instance, the second electrode CE2 may overlap the first optical layer 117a. For example, the second electrode CE2 may cover an outer planar surface of the first optical layer 117a.

The second electrode CE2 may extend continuously in the first direction (X-axis direction) of the substrate 110. Accordingly, the second electrode CE2 may be connected in common to the plurality of pixels PX that are arranged in the first direction (X-axis direction) of the substrate 110. For example, the second electrode CE2 may be connected in common to the plurality of pixels PX.

According to the present specification, the second electrode CE2 may extend continuously on the first optical layer 117a, the second optical layer 117b, and the light-emitting element ED. The area where the first optical layer 117a is located may include a concave portion that is recessed inward relative to the upper surface of the second optical layer 117b. Accordingly, a first portion of the second electrode CE2 located on the first optical layer 117a may be provided along the concave portion and, therefore, may be positioned lower than a second portion of the second electrode CE2 located on the second optical layer 117b.

A third optical layer 117c may be located on the second electrode CE2. The third optical layer 117c may be located to overlap the plurality of light-emitting elements ED and the first optical layer 117a. Since the third optical layer 117c is located on the second electrode CE2 and the plurality of light-emitting elements ED, mura may be prevented from occurring in some of the plurality of light-emitting elements ED. For example, when the plurality of light-emitting elements ED are transferred onto the substrate 110 of the display device 1000, process deviations or other factors may result in non-uniform spacing between the plurality of light-emitting elements ED. If the spacing between the plurality of light-emitting elements ED is non-uniform, respective light output areas of the plurality of light-emitting elements ED may be arranged non-uniformly, making mura visible to a user. Taking into account the aforementioned issue, the third optical layer 117c may be configured to uniformly diffuse light over the plurality of light-emitting elements ED, thereby reducing the perception of mura caused by light emission from some light-emitting elements ED. Therefore, the third optical layer 117c enables light emitted from the plurality of light-emitting elements ED to be evenly diffused and extracted to the outside of the display device 1000, thereby improving the luminance uniformity of the display device 1000.

The third optical layer 117c may be formed of an organic insulating material in which fine particles are dispersed. However, embodiments of the present specification are not limited thereto. For example, the third optical layer 117c may be formed of siloxane in which fine metal particles, such as titanium dioxide (TiO₂) particles, are dispersed; however, embodiments of the present specification are not limited thereto. For example, the third optical layer 117c may be formed of the same material as the first optical layer 117a, but embodiments of the present specification are not limited thereto. For example, the third optical layer 117c may be a diffusion layer or an upper surface diffusion layer; however, embodiments of the present specification are not limited thereto.

According to the present specification, light emitted from the plurality of light-emitting elements ED may be scattered by the fine particles dispersed in the third optical layer 117c and emitted to the outside of the display device 1000. The third optical layer 117c may evenly mix the light emitted from the plurality of light-emitting elements ED, thereby further improving the luminance uniformity of the display device 1000. In addition, scattering the light using the plurality of fine particles may enhance the light extraction efficiency of the display device 1000, thereby enabling the display device 1000 to operate with lower power consumption.

In the display area AA, a black matrix BM may be located on the second electrode CE2, the first optical layer 117a, the second optical layer 117b, and the third optical layer 117c. For example, the black matrix BM may fill the contact hole of the second optical layer 117b. Because the black matrix BM is configured to cover the display area AA, the black matrix BM may reduce color mixing of light from the plurality of sub-pixels and reflection of external light. For example, the black matrix BM may also be located in the contact hole through which the second electrode CE2 and the contact electrode CCE are connected, thereby preventing light leakage between adjacent sub-pixels.

For example, the black matrix BM may be formed of an opaque material. However, embodiments of the present specification are not limited thereto. For instance, the black matrix BM may be an organic insulating material containing a black pigment or a black dye, but embodiments of the present specification are not limited thereto.

In the display area AA, a cover layer 118 may be located on the black matrix BM. The cover layer 118 may protect components provided under the cover layer 118. For example, the cover layer 118 may be formed of an organic insulating material; however, embodiments of the present specification are not limited thereto. For example, the cover layer 118 may be formed of photoresist, polyimide (PI), a photoacryl-based material, or the like, but embodiments of the present specification are not limited thereto. For instance, the cover layer 118 may be an overcoating layer, an insulating layer, or the like; however, embodiments of the present specification are not limited thereto.

The polarizing layer 293 may be located on the cover layer 118 via a first adhesive layer 291. The cover 120 may be located on the polarizing layer 293 via a cover adhesive layer 295. For example, the first adhesive layer 291 and the cover adhesive layer 295 may each include an optically clear adhesive (OCA), an optically clear resin (OCR), a pressure-sensitive adhesive (PSA), or the like. However, embodiments of the present specification are not limited thereto.

According to the present specification, in the second non-display area NA2, the plurality of pad electrodes PE may be arranged on the third insulating layer 115c. For example, at least a portion of each of the plurality of pad electrodes PE may be exposed from the passivation layer 116. For example, the plurality of pad electrodes PE may be electrically connected to the second-4 connection wires 122d through contact holes of the third insulating layer 115c.

A conductive adhesive layer ACF may be located on the plurality of pad electrodes PE. The conductive adhesive layer ACF may be an adhesive layer in which conductive balls are dispersed in an insulating material, but embodiments of the present specification are not limited thereto. In the case where heat or pressure is applied to the conductive adhesive layer ACF, the conductive balls in the area where heat or pressure is applied may be electrically connected, thereby exhibiting conductive properties. The flexible circuit board (or the flexible film) CB may be attached or bonded to the plurality of pad electrodes PE by locating the conductive adhesive layer ACF between the plurality of pad electrodes PE and the flexible circuit board (or flexible film) CB. For example, the conductive adhesive layer ACF may be an anisotropic conductive film (ACF), but embodiments of the present specification are not limited thereto.

The flexible circuit board (or a flexible film) CB may be located on the conductive adhesive layer ACF. The flexible circuit board (or the flexible film) CB may be electrically connected to the plurality of pad electrodes PE through the conductive adhesive layer ACF. Accordingly, signals output from the flexible circuit board (or the flexible film) CB and the printed circuit board may be transmitted to the pixel driving circuit PD in the display area AA through the plurality of pad electrodes PE, the second-fourth connection wire 122d, the second-third connection wire 122c, the second-second connection wire 122b, and the second-first connection wires 122a.

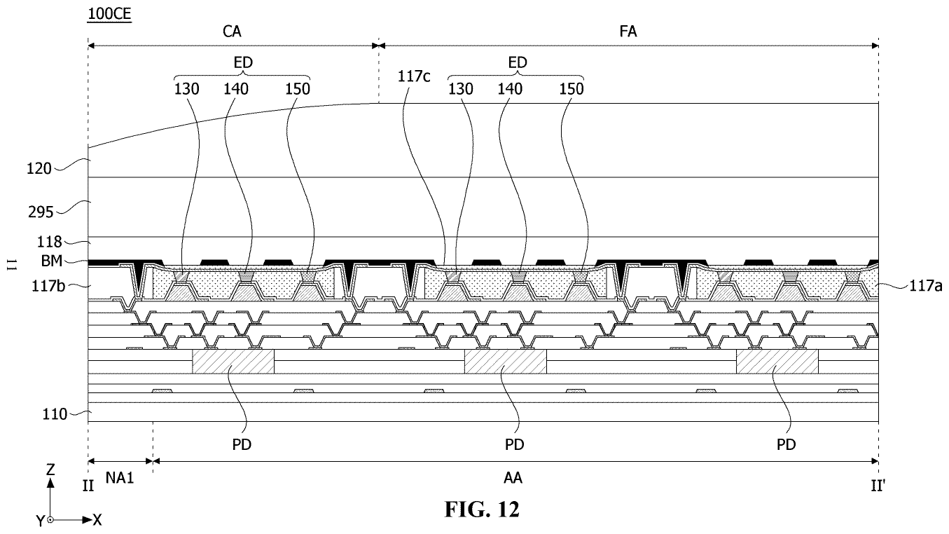

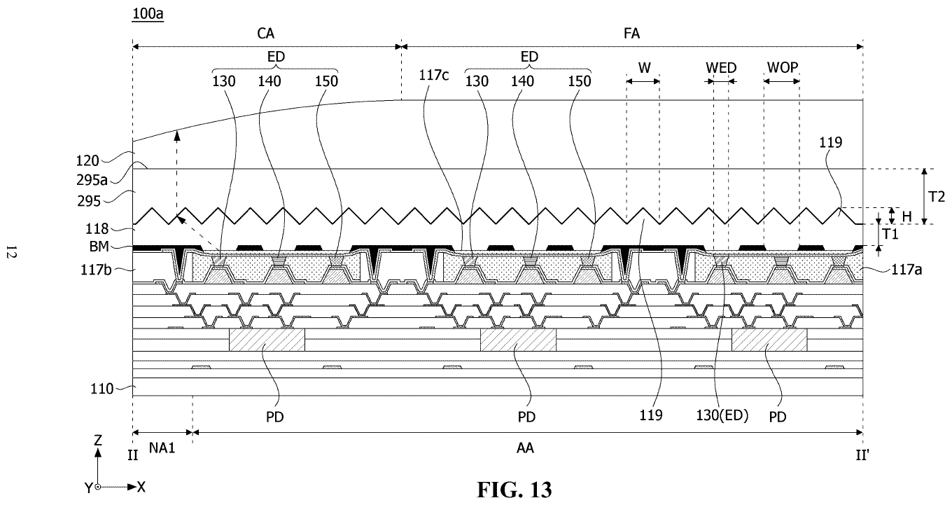

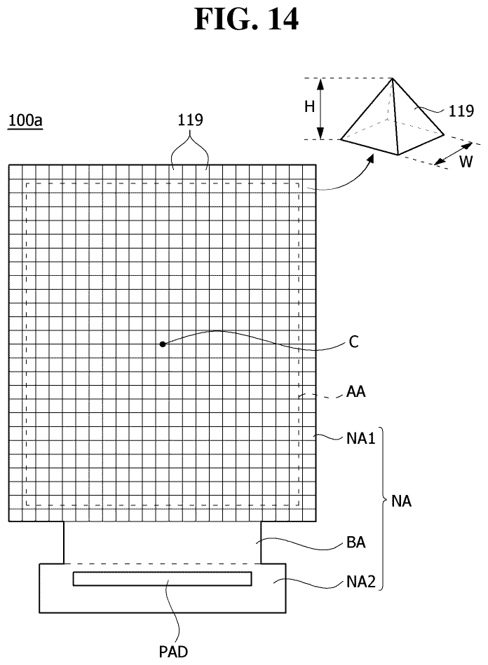

FIG. 12 is a sectional view illustrating a display panel of a display device according to a comparative example. For example, FIG. 12 is a sectional view according to a comparative example, corresponding to a sectional view taken along line II-II′ of FIG. 2. FIG. 13 is a sectional view illustrating a display panel of a display device according to another embodiment of the present specification. For example, FIG. 13 is a sectional view illustrating another embodiment of the display panel taken along line II-II′ of FIG. 2. Here, the display panel illustrated in FIG. 13 may be a display panel 100a according to a second embodiment and may be used in the display device 1000 in place of the display panel 100 according to the first embodiment illustrated in FIG. 8. FIG. 14 is a plan view illustrating a pattern provided in the display panel according to another embodiment of the present specification. For example, FIG. 14 is a plan view illustrating the pattern provided in the display panel according to the second embodiment of the present specification.

In comparing the display device 1000 including the display panel 100 according to the first embodiment with a display device 1000 including a display panel 100CE according to the comparative example, with reference to FIGS. 8 and 12, the display device 1000 including the display panel 100 according to the first embodiment may further include the first adhesive layer 291 and the polarizing layer 293. For example, the display device including the display panel 100CE according to the comparative example may differ from the display device 1000 including the display panel 100 according to the first embodiment in that the adhesion of the cover 120 is achieved via the cover adhesive layer 295 without the first adhesive layer 291 and the polarizing layer 293.

In comparing the display device 1000 including the display panel 100 according to the first embodiment with the display device 1000 including the display panel 100a according to the second embodiment, with reference to FIGS. 8 and 13, the display device 1000 including the display panel 100 according to the first embodiment differs from the display device 1000 including the display panel 100a according to the second embodiment in that the display device 1000 according to the first embodiment further includes the first adhesive layer 291 and the polarizing layer 293 without including a pattern 119. However, in some cases, the display device 1000 including the display panel 100a according to the second embodiment may further include the first adhesive layer 291 and the polarizing layer 293, which are located between the pattern 119 and the cover adhesive layer 295. Here, the cover adhesive layer 295 of the display panel 100a according to the second embodiment may correspond to the cover adhesive layer 295 of the display panel 100 according to the first embodiment.

In comparing the display device including the display panel 100CE according to the comparative example with the display device 1000 including the display panel 100a according to the second embodiment, the display panel 100a according to the second embodiment may further include the pattern 119. Accordingly, the display panel 100a according to the second embodiment can achieve higher efficiency in terms of scattered light efficiency (%) compared to the display panel 100CE according to the comparative example, thereby preventing or minimizing the occurrence of mura at oblique viewing angles. Here, the scattered light efficiency (%) may be a value expressed as a percentage by dividing the luminance measured at an oblique viewing angle by the luminance measured at a normal viewing angle. The luminance at the normal viewing angle may refer to the luminance of the display panel measured on the front of the display panel, i.e., at an angle of 90 degrees relative to the plane of the cover 120. The luminance at the oblique viewing angle may refer to the luminance of the display panel measured at an angle of 75 degrees relative to the plane of the cover 120.

In the following description of the display panel 100a according to the second embodiment with reference to FIGS. 8 and 13, substantially the same components of the display panel 100 according to the first embodiment and the display panel 100a according to the second embodiment may be denoted by the same reference numerals, and thus, a detailed description thereof will be omitted.

Referring to FIGS. 8 and 13, the display panel 100a according to the second embodiment may include a first buffer layer 111a located on the substrate 110, an alignment key MK located on the first buffer layer 111a, a second buffer layer 111b located on the first buffer layer 111a to cover the alignment key MK, a circuit adhesive layer 112 located on the second buffer layer 111b, a pixel driving circuit PD located on the circuit adhesive layer 112, a first protective layer 113a and a second protective layer 113b located on the circuit adhesive layer 112 and configured to enclose a side surface of the pixel driving circuit PD, a first connection wire 121, a third protective layer 114 located on the second protective layer 113b, first, second and third insulating layers 115a, 115b, and 115c, a plurality of contact electrodes CCE, a bank BNK, a passivation layer 116, and a plurality of signal wires TL located on a third insulating layer 115c of the insulating layers, a first electrode CE1 located on the bank BNK, a solder pattern SDP located on the first electrode CE1, a plurality of light-emitting elements ED located on the solder pattern SDP, first, second and third optical layers 117a, 117b, and 117c enclosing the plurality of light-emitting elements ED, a second electrode CE2 located on the light-emitting elements ED, a black matrix BM and a cover layer 118 located on the first, second and third optical layers 117a, 117b, and 117c, at least one pattern 119 located on the cover layer 118, a cover adhesive layer 295 covering the at least one pattern 119, and a cover 120 located on the cover adhesive layer 295. The cover 120 may include a planar area FA and a curved area CA formed around the planar area FA. The curved area CA may include a curved surface. For example, the curved area CA of the cover 120 may overlap a portion of the display area AA and the first non-display area NA1.

Furthermore, the display panel 100a according to the second embodiment may include a plurality of second connection wires 122 located on the second protective layer 113b in the non-display area NA, a plurality of pad electrodes PE located on the plurality of second connection wires 122, and a conductive adhesive layer ACF located on the plurality of pad electrodes PE.

At least one or multiple patterns 119 may be located on light emission paths of the light-emitting elements ED. Furthermore, scattered light of the light emitted from the light-emitting elements ED may be refracted by the at least one or multiple patterns 119. Accordingly, as the scattered light is refracted by the at least one or multiple patterns 119, the light collection efficiency can be improved.

The at least one or multiple patterns 119 may be located on the cover layer 118. For example, the at least one or multiple patterns 119 may be formed to protrude from the cover layer 118. Furthermore, the at least one or multiple patterns 119 may be integrally formed with the cover layer 118. However, embodiments of the present specification are not limited thereto.

Referring to FIG. 13, a plurality of patterns 119 may be arranged in the display area AA and the first non-display area NA1. In this case, at least one pattern 119 located in the first non-display area NA1 may collect scattered light toward a front surface of the cover 120. For example, since scattered light emitted toward the side of the display panel 100a is refracted by the pattern 119, the scattered light efficiency (or light collection efficiency) may be improved by the pattern 119. Accordingly, the display device 1000 may prevent or minimize mura formation in the curved area CA of the cover 120 through the pattern 119. For example, a dashed arrow shown in FIG. 13 may represent a light path of scattered light of the light emitted from the light-emitting element ED. Referring to the light path of the scattered light, the scattered light emitted toward the side of the display panel 100a may be collected toward the front surface of the cover 120 by the pattern 119. For example, the front surface of the cover 120 refers to one surface of the cover 120, which may be a surface opposite to a rear surface of the cover 120 facing the light-emitting element ED or a surface on which images of the display device 1000 are displayed.

The pattern 119 may be provided as a structure having a width W and a height H. For example, the pattern 119 may be formed in a conical shape, a triangular pyramid shape, a quadrangular pyramid shape, a pentagonal pyramid shape, a hexagonal pyramid shape, or the like. However, embodiments of the present specification are not limited thereto.

As illustrated in FIG. 14, the pattern 119 may be formed in a pyramidal shape. The pyramidal patterns 119 may be arranged in the display area AA and the first non-display area NA1. However, embodiments of the present specification are not limited thereto. The width W of the pyramidal pattern 119 may be greater than the height H. For example, the width W of the pyramidal pattern 119 may be twice the height H, but the embodiments of the present specification are not limited thereto.

The width W of the pattern 119 may be adjusted in various ways, taking into account a scattering range of the scattered light of the light emitted from the light-emitting element ED.

The width W of the pattern 119 may be greater than a width WED of the light-emitting element ED. For example, the cover layer 118 may be formed of a material different from that of the optical layer, i.e., the third optical layer 117c, and a refractive index of the cover layer 118 may differ from that of the third optical layer 117c. Accordingly, since the cover layer 118 is a different medium from the third optical layer 117c, a portion of the light emitted from the light-emitting element ED may be scattered. Taking into account the scattering range of the scattered light, the width W of the pattern 119 may be greater than the width WED of the light-emitting element ED. In the case where the height H of the pattern 119 is smaller than a first thickness T1 of the cover layer 118 and a second thickness T2 of the cover adhesive layer 295, the width W of the pattern 119 may be formed to be equal to or similar to a width WOP of an opening formed between the black matrixes BM. However, embodiments of the present specification are not limited thereto. For example, the opening formed between the black matrixes BM may overlap the light-emitting element ED.

In order to reflect the light, which is reflected toward the third optical layer 117c by the pattern 119, toward a front side of the cover 120, a refractive index of the third optical layer 117c may be greater than that of the cover layer 118. In this case, a refractive index of the cover adhesive layer 295 may be greater than that of the third optical layer 117c. Accordingly, the refractive index of the third optical layer 117c may be greater than that of the cover layer 118 and smaller than that of the cover adhesive layer 295.

The height H of the pattern 119 may adjust the position at which scattered light is refracted. For example, because scattered light may be refracted at a surface (or upper surface) of the pattern 119 that meets the cover adhesive layer 295, the position at which the scattered light is refracted may be adjusted by the height H of the pattern 119. For example, as the height H of the pattern 119 increases, the distance from the surface (or upper surface) of the pattern 119 to an upper surface 295a of the cover adhesive layer 295 may be reduced. Accordingly, since the optical path in the pattern 119 becomes longer, the scattered light efficiency of the display panel due to the pattern 119 may be improved, but embodiments of the present specification are not limited thereto. For example, the scattered light efficiency of the display panel may be improved only when the width W and the height H of the pattern 119 are formed to be at least a predetermined size relative to the second thickness T2 of the cover adhesive layer 295. Because the height H of the pattern 119 corresponds to the width W of the pattern 119, the height H of the pattern 119 may increase as the width W increases.

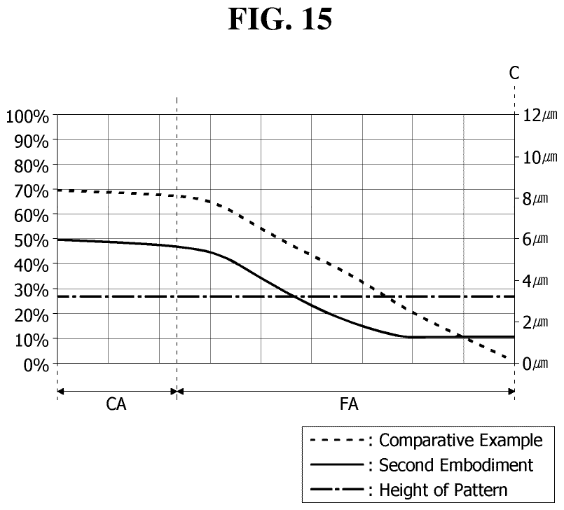

FIG. 15 is a diagram illustrating the scattered light efficiency of the display panel according to the comparative example, the scattered light efficiency of the display panel according to another embodiment, and the height of the pattern, based on the planar area and the curved area of the cover. For example, FIG. 15 illustrates the scattered light efficiency of the display panel according to the comparative example, the scattered light efficiency of the display panel according to the second embodiment, and the height of the pattern, based on the planar area and the curved area of the cover. Here, a left vertical axis of FIG. 15 represents the scattered light efficiency, and a right vertical axis represents the height of the pattern 119. The second thickness T2 of the cover adhesive layer 295 may be 10 μm. Accordingly, the width W and the height H of the pattern 119 may be smaller than the second thickness T2 of the cover adhesive layer 295. Furthermore, the scattered light efficiency (%) may be a value expressed as a percentage by dividing the luminance measured at an oblique viewing angle by the luminance measured at the normal viewing angle. The luminance at the normal viewing angle may refer to the luminance of the display panel measured on the front of the display panel, i.e., at an angle of 90 degrees relative to the plane of the cover 120. The luminance at the oblique viewing angle may refer to the luminance of the display panel measured at an angle of 75 degrees relative to the plane of the cover 120.

With reference to FIGS. 13 and 15, the pattern 119 of the display panel 100a according to the second embodiment may be formed to have the width W and the height H. For example, the width W and the height H of the pattern 119 may be formed to be smaller than the second thickness T2 of the cover adhesive layer 295. For instance, the second thickness T2 of the cover adhesive layer 295 may be 10 μm, the width W of the pattern 119 may be 6.4 μm, and the height H of the pattern 119 may be 3.2 μm.

Even if the display panel 100a according to the second embodiment includes the pattern 119, if the width W and the height H of the pattern 119 do not reach a predetermined size, it may be difficult to secure the scattered light efficiency (%) achieved by the pattern 119. As a result, mura may form in the curved area CA of the cover 120 provided in the display panel 100a according to the second embodiment. For example, as shown in FIG. 15, because the display panel 100a according to the second embodiment exhibits a lower scattered light efficiency than the display panel 100CE according to the comparative example, considering that mura may occur in the display panel 100CE according to the comparative example, there is a possibility that mura may also occur in the curved area CA of the cover 120 provided in the display panel 100a according to the second embodiment.

Therefore, although the display panel 100a according to the second embodiment may not be sufficient to prevent mura, it can be understood that the scattered light efficiency can be adjusted through the pattern 119 of the display panel 100a according to the second embodiment.

Accordingly, the display device 1000 according to an embodiment of the present specification may prevent the occurrence of mura at oblique viewing angles through various embodiments of patterns with different sizes, shapes, and arrangement positions from the pattern 119 of the display panel 100a according to the second embodiment. For example, the display device 1000 according to an embodiment of the present specification may prevent or minimize the occurrence of mura at oblique viewing angles by providing various embodiments of patterns formed by adjusting the size, shape, and arrangement position of the pattern 119.

Hereinafter, various embodiments of patterns capable of preventing or minimizing the occurrence of mura at an oblique viewing angles will be described.

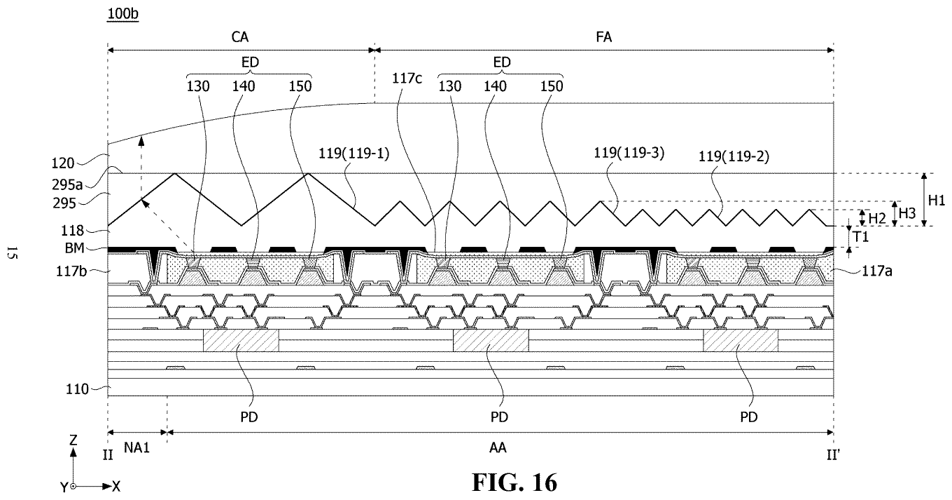

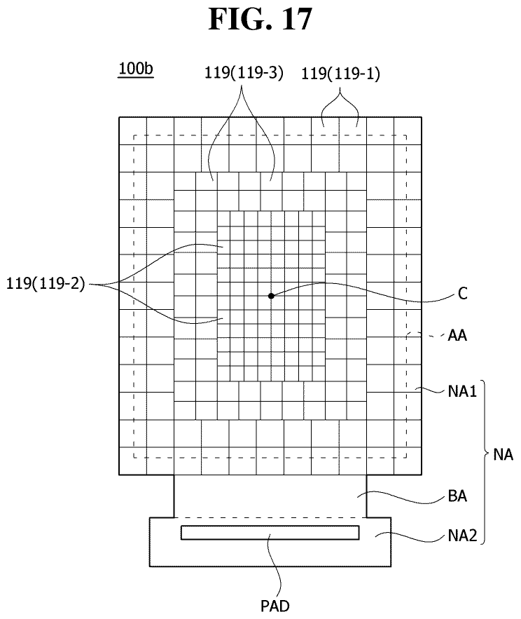

FIG. 16 is a sectional view of a display panel of a display device along line II-II′ of FIG. 2 according to another embodiment of the present specification. For example, FIG. 16 is a sectional view illustrating another embodiment of the display panel taken along line II-II′ of FIG. 2. For instance, the display panel illustrated in FIG. 16 may be a display panel 100b according to a third embodiment and may be used in the display device 1000 in place of the display panel 100a according to the second embodiment. A dashed arrow illustrated in FIG. 16 may represent a light path of scattered light of the light emitted from a light-emitting element ED. FIG. 17 is a plan view illustrating patterns arranged in the display panel according to another embodiment of the present specification. For example, FIG. 17 is a plan view illustrating patterns arranged in the display panel according to the third embodiment of the present specification.

In comparing the display device 1000 including the display panel 100a according to the second embodiment with the display device 1000 including the display panel 100b according to the third embodiment with reference to FIGS. 13 and 16, there is a difference in that, in the display device 1000 including the display panel 100b according to the third embodiment, the sizes of patterns 119 located around a center C of the display panel 100b and patterns 119 located in a perimeter thereof are different. For example, the display panel 100b according to the third embodiment may include patterns 119 that increase in size from the center C of the display panel 100b toward the first non-display area NA1. Furthermore, the display panel 100b according to the third embodiment may include a plurality of pattern groups including a plurality of patterns 119 of different sizes. For example, among the plurality of pattern groups, a pattern group including relatively large patterns 119 may be located at the outermost side of the display panel 100b.

In the following description of the display panel 100b according to the third embodiment with reference to FIGS. 8, 13, and 16, substantially the same components of the display panel 100 according to the first embodiment, the display panel 100a according to the second embodiment, and the display panel 100b according to the third embodiment may be denoted by the same reference numerals, and thus, a detailed description thereof will be omitted.

Referring to FIGS. 8 and 16, the display panel 100b according to the third embodiment may include a first buffer layer 111a, an alignment key MK, a second buffer layer 111b, a circuit adhesive layer 112, a pixel driving circuit PD, a first protective layer 113a, a second protective layer 113b, a first connection wire 121, a third protective layer 114, first, second and third insulating layers 115a, 115b, and 115c, a plurality of contact electrodes CCE, a bank BNK, a passivation layer 116, a plurality of signal wires TL, a first electrode CE1, a solder pattern SDP, a light-emitting element ED, first, second and third optical layers 117a, 117b, and 117c, a second electrode CE2, a black matrix BM, a cover layer 118, at least one pattern 119, a cover adhesive layer 295, and a cover 120. Here, the cover 120 may include a planar area FA and a curved area CA formed around the planar area FA, and the curved area CA may include a curved surface. For example, the curved area CA of the cover 120 may overlap a portion of the display area AA and the first non-display area NA1.

In addition, the display panel 100b according to the third embodiment may include a plurality of second connection wires 122, a plurality of pad electrodes PE, and a conductive adhesive layer ACF.

The plurality of patterns 119 of the display panel 100b according to the third embodiment may be arranged along the light emission paths of the light-emitting elements ED. In addition, scattered light of the light emitted from the light-emitting elements ED may be refracted by the patterns 119. Accordingly, as the scattered light is refracted by the patterns 119, the light collection efficiency can be improved.

The plurality of patterns 119 may be arranged on the cover layer 118. For example, the patterns 119 may be formed to protrude from the cover layer 118. In addition, the patterns 119 may be integrally formed with the cover layer 118; however, embodiments of the present specification are not limited thereto.

The plurality of patterns 119 may be arranged in the display area AA and the first non-display area NA1. For example, the plurality of patterns 119 may overlap the curved area CA and the planar area FA of the cover 120.

The plurality of patterns 119 may increase in size from the display area AA toward the non-display area NA. For example, the plurality of patterns 119 may increase in size from the center C of the display area AA toward the first non-display area NA1.

Taking into account both the difficulty in securing satisfactory scattered light efficiency (%) of the patterns 119 if the width W and the height H of the patterns 119 do not reach a predetermined size, and the possibility that scattered light emitted from the light-emitting elements ED located at the outermost side of the display area AA may form mura in the curved area CA of the cover 120, the patterns 119 overlapping the light-emitting elements ED located at the outermost side of the display area AA or overlapping the first non-display area NA1 may be formed to have a predetermined height H. In other words, the patterns 119 overlapping the curved area CA of the cover 120 may be formed to have a predetermined height H, taking into account the scattered light efficiency (%). For example, if the second thickness T2 of the cover adhesive layer 295 is defined as 1, the height H of the patterns 119 overlapping the curved area CA of the cover 120 may be 0.5 to 1.0 times the second thickness T2 of the cover adhesive layer 295. In the case where each pattern 119 is formed in a pyramid shape, such as a quadrangular pyramid shape, the width W of the pattern 119 may increase as the height H of the pattern 119 increases.

Referring to FIG. 16, the plurality of patterns 119 may include a first pattern 119-1 overlapping the curved area CA of the cover 120, a second pattern 119-2 located at or adjacent to the center C of the display panel 100b, and a third pattern 119-3 located between the first pattern 119-1 and the second pattern 119-2. The second pattern 119-2 and the third pattern 119-3 may overlap the planar area FA of the cover 120. Furthermore, the numbers of first patterns 119-1, second patterns 119-2, and third patterns 119-3 may be adjustable.

A first height H1 of the first pattern 119-1 may be greater than a second height H2 of the second pattern 119-2. Furthermore, a third height H3 of the third pattern 119-3 may be greater than the second height H2 of the second pattern 119-2. Accordingly, the first height H1 of the first pattern 119-1 overlapping the curved area CA may be greater than the heights H2 and H3 of the second patterns 119-2 and third 119-3 overlapping the planar area FA.

The first height H1 of the first pattern 119-1 may be formed to be equal to or greater than a preset height. For example, the first height H1 of the first pattern 119-1 may be 0.5 to 1.0 times the second thickness T2 of the cover adhesive layer 295. For instance, taking into account non-contact between the first pattern 119-1 and the cover 120, the first height H1 of the first pattern 119-1 may be 0.5 to 0.95 times the second thickness T2 of the cover adhesive layer 295, but is not necessarily limited thereto. Here, the first light-emitting elements 130, which are arranged at the outermost side of the display panel 100b with reference to the center C of the display panel 100b, may be located to overlap the first pattern 119-1 to prevent or minimize the formation of mura on the cover 120.

In addition, the first light-emitting element 130, the second light-emitting element 140, and the third light-emitting element 150, which are arranged at the outermost side of the display area AA and form a single pixel PX, may overlap the first patterns 119-1 overlapping the curved area CA of the cover 120 to prevent or minimize the formation of mura on the cover 120. Here, since the first light-emitting element 130 is located in the first sub-pixel SP1, the second light-emitting element 140 is located in the second sub-pixel SP2, and the third light-emitting element 150 is located in the third sub-pixel SP3 to form a single pixel PX, the first light-emitting element 130, the second light-emitting element 140, and the third light-emitting element 150, which are arranged at the outermost side of the display area AA and form the pixel PX may overlap the first patterns 119-1. Hence, the formation of mura on the cover 120 can be prevented or minimized. In other words, as the light-emitting elements ED located at the outermost side of the display area AA to form a single pixel PX overlap the first patterns 119-1, the formation of mura on the cover 120 can be prevented or minimized. For example, as the pixels PX located at the outermost side of the display area AA overlap the first patterns 119-1, the formation of mura on the cover 120 can be prevented or minimized.

Accordingly, in the display panel 100b according to the third embodiment, as the first height H1 of the first pattern 119-1 overlapping the curved area CA is formed within a range of 0.5 to 1.0 times the second thickness T2 of the cover adhesive layer 295, the formation of mura on the cover 120 can be prevented, reduced, or minimized.

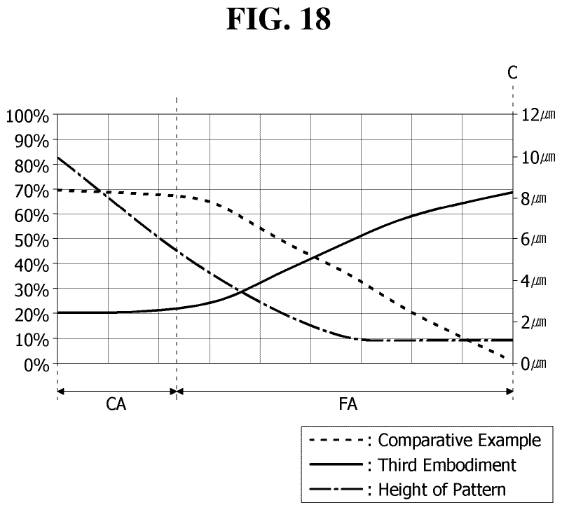

FIG. 18 is a diagram illustrating the scattered light efficiency of the display panel according to the comparative example, the scattered light efficiency of the display panel according to another embodiment, and the height of the pattern, based on the planar area and the curved area of the cover. For example, FIG. 18 illustrates the scattered light efficiency of the display panel according to the comparative example, the scattered light efficiency of the display panel according to the third embodiment, and the height of the pattern, based on the planar area and the curved area of the cover. Here, a left vertical axis of FIG. 18 represents the scattered light efficiency, and a right vertical axis represents the height of the pattern 119. The second thickness T2 of the cover adhesive layer 295 may be 10 μm. The height H of the pattern 119 may be smaller than or equal to the second thickness T2 of the cover adhesive layer 295.

Referring to FIG. 18, the patterns 119 of the display panel 100b according to the third embodiment may increase in size toward the first non-display area NA1 based on the center C of the display panel 100b. For example, the height H of the patterns 119 may increase toward the first non-display area NA1. The height H of the patterns 119 located at the outermost side of the display panel 100b may be equal to the second thickness T2 of the cover adhesive layer 295. For example, the second thickness T2 of the cover adhesive layer 295 may be 10 μm. Additionally, the height H of the patterns 119 overlapping the curved area CA of the cover 120 may be formed within a range of 0.5 to 1.0 times the second thickness T2 of the cover adhesive layer 295. Furthermore, the height H of the patterns 119 located at the outermost side of the display panel 100b may be formed within a range of 0.5 to 1.0 times the second thickness T2 of the cover adhesive layer 295.

Referring to FIGS. 16 to 18, the scattered light efficiency of the display panel 100b according to the third embodiment is less than that of the display panel 100CE according to the comparative example, at the outermost side of the display panel. Accordingly, the display panel 100b according to the third embodiment may prevent occurrence of mura at oblique viewing angles by utilizing the first pattern 119-1 located at the outermost side of the display panel 100b.

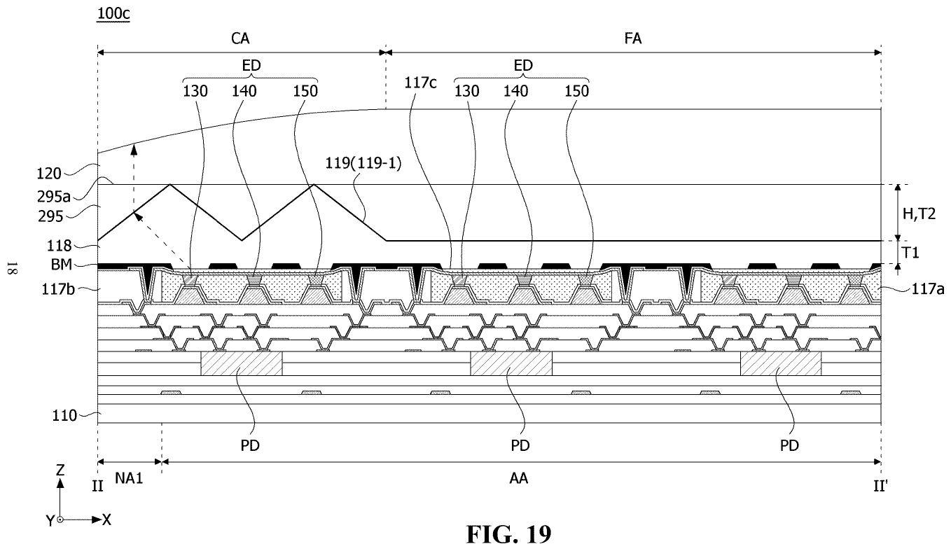

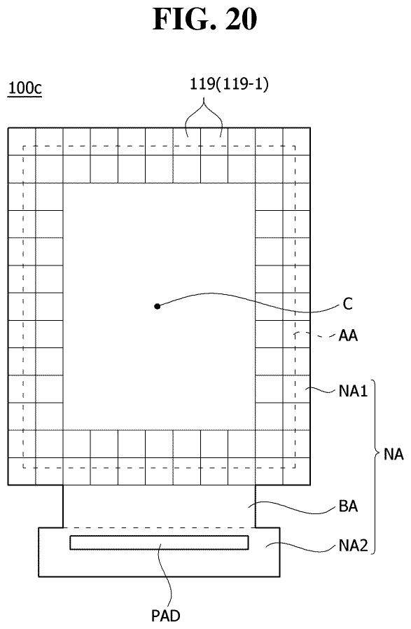

FIG. 19 is a sectional view of a display panel of a display device according to another embodiment of the present specification. For example, FIG. 19 is a sectional view illustrating another embodiment of the display panel along line II-II′ of FIG. 2. For example, the display panel illustrated in FIG. 19 may be a display panel 100c according to a fourth embodiment and may be used in the display device 1000 in place of the display panel 100a according to the second embodiment. A dashed arrow illustrated in FIG. 19 may represent a light path of scattered light of the light emitted from a light-emitting element ED. FIG. 20 is a plan view illustrating patterns arranged in the display panel according to another embodiment of the present specification. For example, FIG. 20 is a plan view illustrating patterns arranged in the display panel according to the fourth embodiment of the present specification.

In comparing the display device 1000 including the display panel 100b according to the third embodiment with the display device 1000 including the display panel 100c according to the fourth embodiment with reference to FIGS. 16 and 19, there is a difference in that, in the display device 1000 including the display panel 100c according to the fourth embodiment, the patterns 119 are arranged only in a perimeter of the display panel 100c. For example, the display panel 100c according to the fourth embodiment may include a plurality of first patterns 119-1 overlapping the curved area CA of the cover 120.

In the following description of the display panel 100c according to the fourth embodiment with reference to FIGS. 8, 13, 16, and 19, substantially the same components of the display panel 100 according to the first embodiment, the display panel 100a according to the second embodiment, the display panel 100b according to the third embodiment, and the display panel 100c according to the fourth embodiment may be denoted by the same reference numerals, and thus, a detailed description thereof will be omitted.

Referring to FIGS. 8 and 19, the display panel 100c according to the fourth embodiment may include a first buffer layer 111a, an alignment key MK, a second buffer layer 111b, a circuit adhesive layer 112, a pixel driving circuit PD, a first protective layer 113a, a second protective layer 113b, a first connection wire 121, a third protective layer 114, first, second and third insulating layers 115a, 115b, and 115c, a plurality of contact electrodes CCE, a bank BNK, a passivation layer 116, a plurality of signal wires TL, a first electrode CE1, a solder pattern SDP, a light-emitting element ED, first, second and third optical layers 117a, 117b, and 117c, a second electrode CE2, a black matrix BM, a cover layer 118, a plurality of patterns 119 overlapping the curved area CA, a cover adhesive layer 295, and a cover 120. Here, the cover 120 may include a planar area FA and a curved area CA formed around the planar area FA, and the curved area CA may include a curved surface. For example, the curved area CA of the cover 120 may overlap a portion of the display area AA and the first non-display area NA1.

In addition, the display panel 100c according to the fourth embodiment may include a plurality of second connection wires 122, a plurality of pad electrodes PE, and a conductive adhesive layer ACF.

The plurality of patterns 119 of the display panel 100c according to the fourth embodiment may be arranged along the light emission paths of the light-emitting elements ED that are located in the perimeter of the display panel 100c. In addition, scattered light of the light emitted from the light-emitting elements ED may be refracted by the patterns 119. Accordingly, as the scattered light is refracted by the patterns 119, the light collection efficiency can be improved.

The plurality of patterns 119 may be arranged on the cover layer 118. For example, the patterns 119 may be formed to protrude from the cover layer 118. Furthermore, the patterns 119 may be integrally formed with the cover layer 118. However, embodiments of the present specification are not limited thereto.

Referring to FIG. 19, the plurality of patterns 119 may be arranged to overlap the curved area CA of the cover 120. Accordingly, the plurality of patterns 119 may be located in a portion of the perimeter of the display area AA and in the first non-display area NA1. Here, the plurality of patterns 119 overlapping the curved area CA of the cover 120 may correspond to the first patterns 119-1. Accordingly, the height H of the patterns 119 overlapping the curved area CA of the cover 120 may be formed within a range of 0.5 to 1.0 times the second thickness T2 of the cover adhesive layer 295, but is not necessarily limited thereto. For example, the height H of the patterns 119 overlapping the curved area CA of the cover 120 may be equal to or slightly smaller than the second thickness T2 of the cover adhesive layer 295. In this case, based on the Z-axis direction, the height H of the patterns 119 may be greater than the first thickness T1 of the cover layer 118. Additionally, the height H of the patterns 119 may be smaller than the width W of the patterns 119.

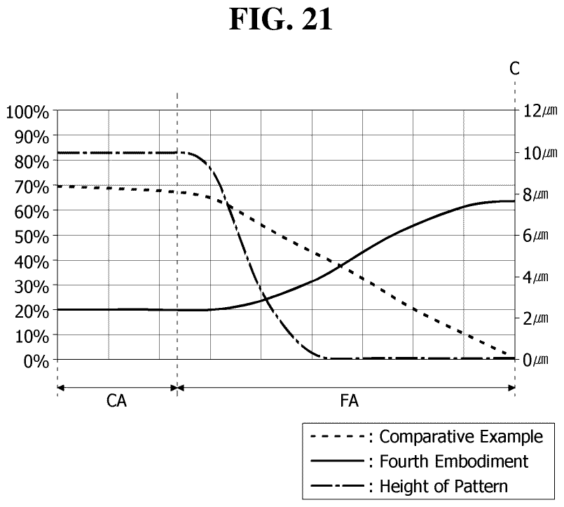

FIG. 21 is a diagram illustrating the scattered light efficiency of the display panel according to the comparative example, the scattered light efficiency of the display panel according to another embodiment, and the height of the pattern, based on the planar area and the curved area of the cover. For example, FIG. 21 illustrates the scattered light efficiency of the display panel according to the comparative example, the scattered light efficiency of the display panel according to the fourth embodiment, and the height of the pattern, based on the planar area and the curved area of the cover. Here, a left vertical axis of FIG. 21 represents the scattered light efficiency, and a right vertical axis represents the height of the pattern 119. The second thickness T2 of the cover adhesive layer 295 may be 10 μm. The height H of the pattern 119 may be smaller than or equal to the second thickness T2 of the cover adhesive layer 295.

Referring to FIG. 19, the patterns 119 of the display panel 100c according to the fourth embodiment may overlap the curved area CA of the cover 120. Accordingly, the patterns 119 of the display panel 100c may not overlap the planar area FA of the cover 120. The height H of the patterns 119 overlapping the curved area CA of the cover 120 may be equal to the second thickness T2 of the cover adhesive layer 295, but is not necessarily limited thereto. For example, the second thickness T2 of the cover adhesive layer 295 may be 10 μm. Furthermore, the height H of the patterns 119 overlapping the curved area CA of the cover 120 may be formed within a range of 0.5 to 1.0 times the second thickness T2 of the cover adhesive layer 295.

Referring to FIGS. 19 to 21, because the scattered light efficiency of the display panel 100c according to the fourth embodiment is less than that of the display panel 100CE according to the comparative example, the display panel 100c according to the fourth embodiment may prevent occurrence of mura at oblique viewing angles by utilizing the patterns 119 that overlap the curved area CA of the cover 120.

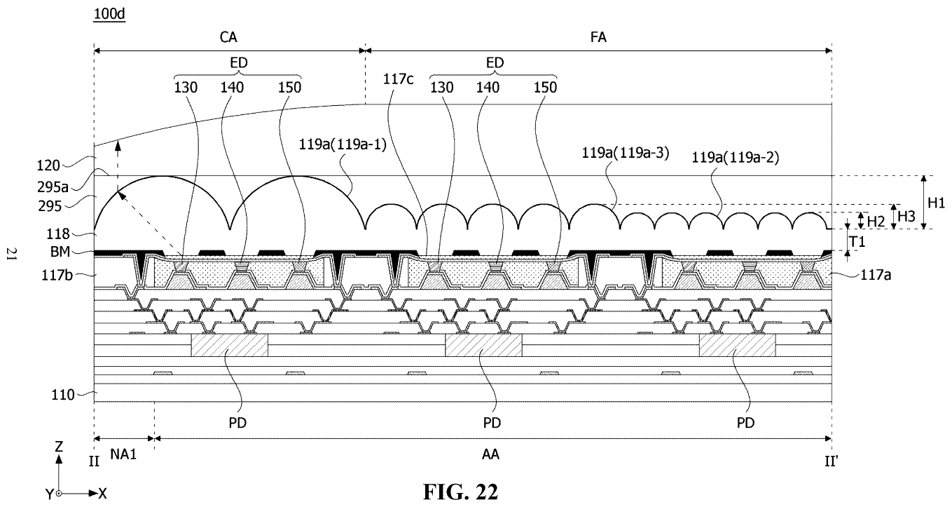

FIG. 22 is a sectional view of a display panel of a display device according to another embodiment of the present specification. For example, FIG. 22 is a sectional view illustrating another embodiment of the display panel taken along line II-II′ of FIG. 2. For instance, the display panel illustrated in FIG. 22 may be a display panel 100d according to a fifth embodiment and may be used in the display device 1000 in place of the display panel 100a according to the second embodiment. A dashed arrow illustrated in FIG. 22 may represent a light path of scattered light of the light emitted from a light-emitting element ED.

In comparing the display device 1000 including the display panel 100b according to the third embodiment with the display device 1000 including the display panel 100d according to the fifth embodiment with reference to FIGS. 16 and 22, there is a difference in the shape of patterns in the display device 1000 including the display panel 100d according to the fifth embodiment. For example, each pattern 119 of the display panel 100b according to the third embodiment may have a pyramidal shape, and each pattern 119a of the display panel 100d according to the fifth embodiment may have a micro-lens shape

In the following description of the display panel 100d according to the fifth embodiment with reference to FIGS. 8, 13, 16, and 22, substantially the same components of the display panel 100 according to the first embodiment, the display panel 100a according to the second embodiment, the display panel 100b according to the third embodiment, and the display panel 100d according to the fifth embodiment may be denoted by the same reference numerals, and thus, a detailed description thereof will be omitted.

Referring to FIGS. 8 and 22, the display panel 100d according to the fifth embodiment may include a first buffer layer 111a, an alignment key MK, a second buffer layer 111b, a circuit adhesive layer 112, a pixel driving circuit PD, a first protective layer 113a, a second protective layer 113b, a first connection wire 121, a third protective layer 114, first, second and third insulating layers 115a, 115b, and 115c, a plurality of contact electrodes CCE, a bank BNK, a passivation layer 116, a plurality of signal wires TL, a first electrode CE1, a solder pattern SDP, a light-emitting element ED, first, second and third optical layers 117a, 117b, and 117c, a second electrode CE2, a black matrix BM, a cover layer 118, a plurality of patterns 119a, a cover adhesive layer 295, and a cover 120. Here, the cover 120 may include a planar area FA and a curved area CA formed around the planar area FA, and the curved area CA may include a curved surface. For example, the curved area CA of the cover 120 may overlap a portion of the display area AA and the first non-display area NA1. Additionally, the plurality of patterns 119a may each have a micro-lens shape.

Furthermore, the display panel 100d according to the fifth embodiment may include a plurality of second connection wires 122, a plurality of pad electrodes PE, and a conductive adhesive layer ACF.

The plurality of patterns 119a arranged in the display panel 100d according to the fifth embodiment may be positioned along the light emission paths of the light-emitting elements ED. In addition, scattered light of the light emitted from the light-emitting elements ED may be refracted by the patterns 119a. Accordingly, as the scattered light is refracted by the patterns 119a, the light collection efficiency can be improved.

The plurality of patterns 119a may be arranged on the cover layer 118. For example, the patterns 119a may be formed to protrude from the cover layer 118. Furthermore, the patterns 119a may be integrally formed with the cover layer 118. However, embodiments of the present specification are not limited thereto.

Referring to FIG. 22, the plurality of patterns 119a may be arranged in the display area AA and the first non-display area NA1. For example, the plurality of patterns 119a may overlap the curved area CA and the planar area FA of the cover 120.

The plurality of patterns 119a may increase in size from the display area AA toward the non-display area NA. For example, the plurality of patterns 119a may increase in size from the center C of the display area AA toward the first non-display area NA1.

Referring to FIG. 22, the plurality of patterns 119a may include a first pattern 119a-1 overlapping the curved area CA of the cover 120, a second pattern 119a-2 located at or adjacent to the center C of the display panel 100d, and a third pattern 119a-3 located between the first pattern 119a-1 and the second pattern 119a-2. Here, the second pattern 119a-2 and the third pattern 119a-3 may overlap the planar area FA of the cover 120.

A first height H1 of the first pattern 119a-1 may be greater than a second height H2 of the second pattern 119a-2. Furthermore, a third height H3 of the third pattern 119a-3 may be greater than the second height H2 of the second pattern 119a-2. Accordingly, the first height H1 of the first pattern 119a-1 overlapping the curved area CA may be greater than the heights H2 and H3 of the second patterns 119a-2 and third patterns 119a-3 overlapping the planar area FA. For example, the first height H1 of the first pattern 119a-1 may be 0.5 to 0.95 times the second thickness T2 of the cover adhesive layer 295, but is not necessarily limited thereto.

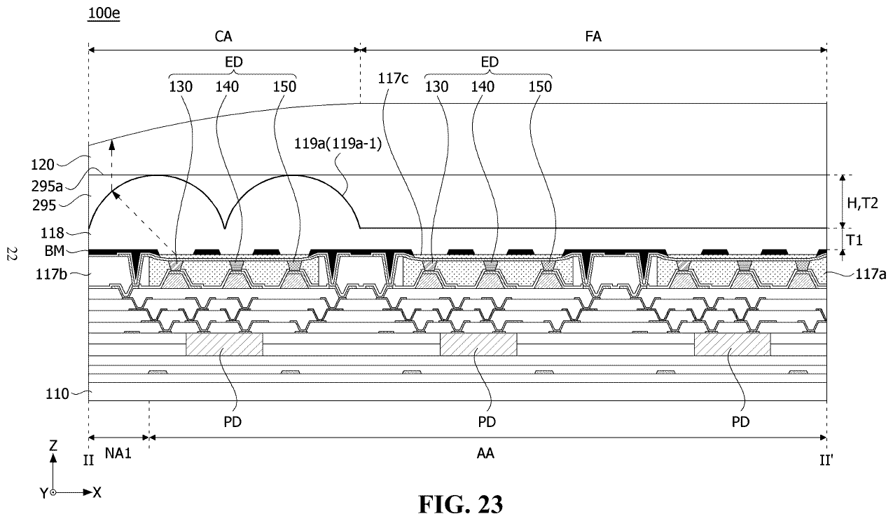

FIG. 23 is a sectional view of a display panel of a display device according to another embodiment of the present specification. For example, FIG. 23 is a sectional view illustrating another embodiment of the display panel along line II-II′ of FIG. 2. For example, the display panel illustrated in FIG. 23 may be a display panel 100e according to a sixth embodiment and may be used in the display device 1000 in place of the display panel 100a according to the second embodiment. A dashed arrow illustrated in FIG. 23 may represent a light path of scattered light of the light emitted from a light-emitting element ED.

In comparing the display device 1000 including the display panel 100c according to the fourth embodiment with the display device 1000 including the display panel 100e according to the sixth embodiment with reference to FIGS. 19 and 23, there is a difference in the shape of patterns in the display device 1000 including the display panel 100e according to the sixth embodiment. For example, each pattern 119 of the display panel 100c according to the fourth embodiment may have a pyramidal shape, and each pattern 119a of the display panel 100e according to the sixth embodiment may have a micro-lens shape.

In the following description of the display panel 100e according to the sixth embodiment with reference to FIGS. 8, 13, 16, 19, and 23, substantially the same components of the display panel 100 according to the first embodiment, the display panel 100a according to the second embodiment, the display panel 100b according to the third embodiment, the display panel 100c according to the fourth embodiment, and the display panel 100e according to the sixth embodiment may be denoted by the same reference numerals, and thus, a detailed description thereof will be omitted.

Referring to FIGS. 8 and 23, the display panel 100e according to the sixth embodiment may include a first buffer layer 111a, an alignment key MK, a second buffer layer 111b, a circuit adhesive layer 112, a pixel driving circuit PD, a first protective layer 113a, a second protective layer 113b, a first connection wire 121, a third protective layer 114, first, second and third insulating layers 115a, 115b, and 115c, a plurality of contact electrodes CCE, a bank BNK, a passivation layer 116, a plurality of signal wires TL, a first electrode CE1, a solder pattern SDP, a light-emitting element ED, first, second and third optical layers 117a, 117b, and 117c, a second electrode CE2, a black matrix BM, a cover layer 118, a plurality of patterns 119a overlapping the curved area CA, a cover adhesive layer 295, and a cover 120. Here, the cover 120 may include a planar area FA and a curved area CA formed around the planar area FA, and the curved area CA may include a curved surface. The curved area CA of the cover 120 may overlap a portion of the display area AA and the first non-display area NA1. Additionally, the plurality of patterns 119a may each have a micro-lens shape.

The display panel 100e according to the sixth embodiment may include a plurality of second connection wires 122, a plurality of pad electrodes PE, and a conductive adhesive layer ACF.

The plurality of patterns 119a arranged in the display panel 100e according to the sixth embodiment may be positioned along the light emission paths of the light-emitting elements ED that are located in the perimeter of the display panel 100c. In addition, scattered light of the light emitted from the light-emitting elements ED may be refracted by the patterns 119a. Accordingly, as the scattered light is refracted by the patterns 119a, the light collection efficiency can be improved.

The plurality of patterns 119a may be arranged on the cover layer 118. For example, the patterns 119a may be formed to protrude from the cover layer 118. Furthermore, the patterns 119a may be integrally formed with the cover layer 118. However, embodiments of the present specification are not limited thereto.

Referring to FIG. 23, the plurality of patterns 119a may be arranged to overlap the curved area CA of the cover 120. Accordingly, the plurality of patterns 119a may be arranged in a portion of the perimeter of the display area AA and in the first non-display area NA1. Here, the plurality of patterns 119a overlapping the curved area CA of the cover 120 may correspond to first patterns 119a-1. Accordingly, the height H of the patterns 119a overlapping the curved area CA of the cover 120 may be formed within a range of 0.5 to 1.0 times the second thickness T2 of the cover adhesive layer 295, but is not necessarily limited thereto. For example, the height H of the patterns 119a overlapping the curved area CA of the cover 120 may be equal to or slightly smaller than the second thickness T2 of the cover adhesive layer 295. For example, based on the Z-axis direction, the height H of the patterns 119a may be greater than the first thickness T1 of the cover layer 118. Additionally, the height H of the patterns 119a may be smaller than the width W of the patterns 119a.

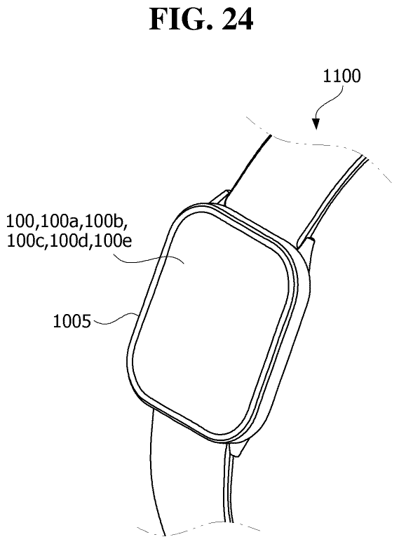

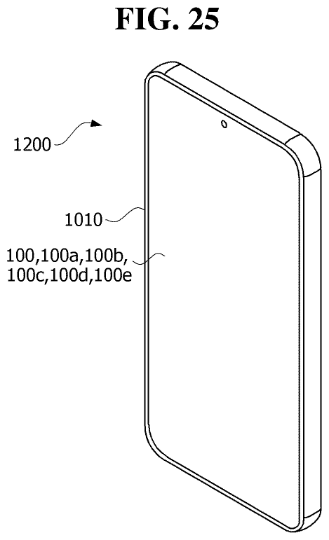

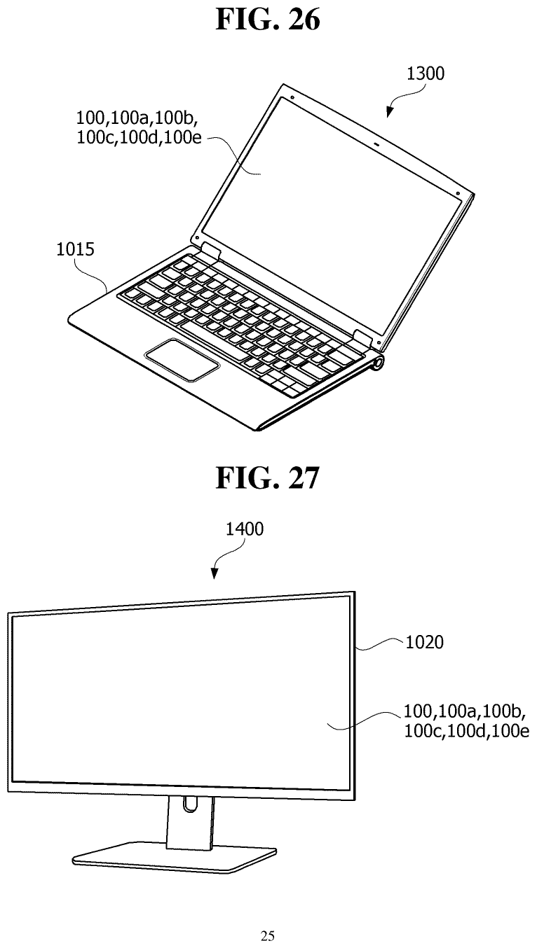

FIGS. 24 to 27 are diagrams illustrating devices to which the display device according to embodiments of the present specification is applied.

Referring to FIGS. 24 to 27, the display device 1000 according to embodiments of the present specification may be included in various devices or electronic devices. For example, as illustrated in FIGS. 24 to 27, various electronic devices may include a wearable device 1100, a mobile device 1200, a laptop 1300, and a monitor or TV 1400, but the embodiments of the present specification are not limited thereto.

Each of the wearable device 1100, the mobile device 1200, the laptop 1300, and the monitor or TV 1400 may respectively include a casing 1005, 1010, 1015, or 1020, and the display device 1000 including the display panel 100, 100a, 100b, 100c, 100d, or 100e according to embodiments of the present specification as described with reference to FIGS. 1 to 23.

For example, the display device according to the embodiment of the present invention may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation device, a vehicle display device, a theater display device, a television, a wallpaper device, a signage device, a game device, a laptop computer, a monitor, a camera, a camcorder, a home appliance, and the like.

The display device according to one or more embodiments of the present invention may be described as follows.

A display device according to one or more embodiments of the present specification may include a display panel, the display panel comprising: a substrate; an insulating layer located on a substrate; a plurality of first electrodes arranged on the insulating layer; a plurality of light-emitting elements arranged on the plurality of first electrodes; a plurality of second electrodes arranged on the plurality of light-emitting elements; an optical layer enclosing the plurality of light-emitting elements; a cover layer located on the optical layer; at least one pattern located on the cover layer; a cover adhesive layer covering the at least one pattern; and a cover located on the cover adhesive layer. The cover may include a planar area, and a curved area formed around the planar area.

According to one or more embodiments of the present specification, the curved area of the cover may overlap the at least one pattern.

According to one or more embodiments of the present specification, the at least one pattern overlapping the curved area may overlap the plurality of light-emitting elements.

According to one or more embodiments of the present specification, a width of each of the plurality of light-emitting elements is less than a width of each of the at least one pattern.

According to one or more embodiments of the present specification, the substrate may include a display area in which the plurality of light-emitting elements are arranged, and a non-display area formed around the display area. A light-emitting element located in an outermost portion of the display area among the plurality of light-emitting elements may overlap the curved area and the at least one pattern.

According to one or more embodiments of the present specification, the substrate may include a display area in which the plurality of light-emitting elements are arranged, and a non-display area formed around the display area. The at least one pattern may include a plurality of patterns. The plurality of patterns may be located in the display area and the non-display area.

According to one or more embodiments of the present specification, the plurality of patterns may increase in height from the display area toward the non-display area.

According to one or more embodiments of the present specification, the height of a pattern overlapping the curved area among the plurality of patterns may be greater than the height of a pattern overlapping the planar area among the plurality of patterns.

According to one or more embodiments of the present specification, the substrate may include a display area in which the plurality of light-emitting elements are arranged, and a non-display area formed around the display area. The at least one pattern may include a plurality of patterns. The plurality of patterns may be located in a perimeter of the display area and the non-display area. A pattern that is located in the display area among the plurality of patterns may overlap the curved area.

According to one or more embodiments of the present specification, a refractive index of the optical layer may be greater than a refractive index of the cover layer and may be less than a refractive index of the cover adhesive layer.

According to one or more embodiments of the present specification, each of the at least one pattern may have a pyramid shape or a micro-lens shape.

According to one or more embodiments of the present specification, the height of each of the at least one pattern may be greater than a thickness of the cover layer.

According to one or more embodiments of the present specification, each of the at least one pattern may have a width and a height which may be less than the width.

According to one or more embodiments of the present specification, the display device may further include a plurality of banks located on the insulating layer. The plurality of first electrodes may be located on the plurality of banks, respectively.

According to one or more embodiments of the present specification, the optical layer may include a first optical layer provided around the plurality of light-emitting elements, a second optical layer located on a side surface of the first optical layer, and a third optical layer located on the plurality of light-emitting elements.

According to one or more embodiments of the present specification, each of the plurality of light-emitting elements may be a micro light-emitting diode (micro LED) made of an inorganic material.

According to one or more embodiments of the present specification, each of the plurality of light-emitting elements may have a vertical structure.

According to one or more embodiments of the present specification, the display device may further include: a passivation layer located on the insulating layer and including a plurality of holes; and a plurality of pattern layers connected to the plurality of first electrodes, and located in the plurality of holes, respectively. The plurality of first electrodes and the plurality of light-emitting elements may be electrically connected by eutectic bonding using the plurality of pattern layers, respectively.

According to one or more embodiments of the present specification, the display device may further include: a pixel driving circuit located on the substrate; and a plurality of connection wires disposed on the substrate and electrically connecting the plurality of first electrodes and the pixel driving circuit.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A display device comprising a display panel, the display panel comprising:
a substrate;
an insulating layer on the substrate;
a plurality of first electrodes on the insulating layer;
a plurality of light-emitting elements on the plurality of first electrodes;
a plurality of second electrodes on the plurality of light-emitting elements;
an optical layer enclosing the plurality of light-emitting elements;
a cover layer on the optical layer;
at least one pattern on the cover layer;
a cover adhesive layer covering the at least one pattern; and
a cover on the cover adhesive layer,
wherein the cover includes a planar area and a curved area, the curved area around the planar area.

2. The display device according to claim 1, wherein the curved area of the cover overlaps the at least one pattern.

3. The display device according to claim 2, wherein the at least one pattern overlaps the curved area and overlaps the plurality of light-emitting elements.

4. The display device according to claim 3, wherein a width of each of the plurality of light-emitting elements is less than a width of each of the at least one pattern.

5. The display device according to claim 1, wherein the substrate includes a display area in which the plurality of light-emitting elements are arranged and a non-display area around the display area, and
wherein a light-emitting element from the plurality of light-emitting elements that is in an outermost portion of the display area overlaps the curved area and the at least one pattern.

6. The display device according to claim 1, wherein the substrate includes a display area in which the plurality of light-emitting elements are arranged and a non-display area around the display area,
wherein the at least one pattern comprises a plurality of patterns and the plurality of patterns are in the display area and the non-display area.

7. The display device according to claim 6, wherein the plurality of patterns increase in height from the display area toward the non-display area.

8. The display device according to claim 6, wherein a height of a pattern from the plurality of patterns that overlaps the curved area is greater than a height of a pattern from the plurality of patterns that overlaps the planar area.

9. The display device according to claim 1, wherein the substrate includes a display area in which the plurality of light-emitting elements are arranged and a non-display area around the display area,
wherein the at least one pattern comprises a plurality of patterns that are located in a perimeter of the display area and the non-display area, and
wherein a pattern from the plurality of patterns that is located in the display area overlaps the curved area.

10. The display device according to claim 1, wherein a refractive index of the optical layer is greater than a refractive index of the cover layer and is less than a refractive index of the cover adhesive layer.

11. The display device according to claim 1, wherein each of the at least one pattern has a pyramid shape or a micro-lens shape.

12. The display device according to claim 1, wherein a height of each of the at least one pattern is greater than a thickness of the cover layer.

13. The display device according to claim 1, wherein each of the at least one pattern has a width and a height which is less than the width.

14. The display device according to claim 1, further comprising:
a plurality of banks on the insulating layer,
wherein the plurality of first electrodes are on the plurality of banks, respectively.

15. The display device according to claim 14, wherein the optical layer comprises:
a first optical layer around the plurality of light-emitting elements,
a second optical layer on a side surface of the first optical layer, and
a third optical layer on the plurality of light-emitting elements.

16. The display device according to claim 14, wherein each of the plurality of light-emitting elements is a micro light-emitting diode made of an inorganic material.

17. The display device according to claim 1, wherein each of the plurality of light-emitting elements has a vertical structure.

18. The display device according to claim 1, further comprising:
a passivation layer on the insulating layer, the passivation layer including a plurality of holes; and
a plurality of pattern layers connected to the plurality of first electrodes, the plurality of pattern layers located in the plurality of holes, respectively,
wherein the plurality of first electrodes and the plurality of light-emitting elements are electrically connected using the plurality of pattern layers, respectively.

19. The display device according to claim 1, further comprising:
a pixel driving circuit on the substrate; and
a plurality of connection wires on the substrate and electrically connecting the plurality of first electrodes and the pixel driving circuit.
